(19) United States
(12) Patent Application Publication
(10) Pub. No.: US 2026/0278198 A1
(43) Pub. Date: Sep. 17, 2026

(54) Determining Physical Cabling Resources For A Data Center Based On A Data Center Model

(71) Applicant: Oracle International Corporation, Redwood Shores, CA (US)

(72) Inventors: Erik Sabiun, Vilnius (LT); Andrew B. Dickinson, Seattle, WA (US); Charles S. Gordon, Mountain View, CA (US); Thomas Patrick Booth, Redmond, WA (US); Manasa Pola, Bothell, WA (US); Helali Bhuiyan, Sammamish, WA (US); Robert Lee Tesch, II, Seattle, WA (US)

(73) Assignee: Oracle International Corporation, Redwood Shores, CA (US)

(21) Appl. No.: 19/229,474

(22) Filed: Jun. 5, 2025

Related U.S. Application Data
(60) Provisional application No. 63/771,165, filed on Mar. 13, 2025.

(51) Int. Cl. G06F 30/18

(52) U.S. Cl. CPC G06F 30/18

(57) ABSTRACT

Techniques for determining cabling resources for a data center are disclosed. A system includes a data center model that includes a first device model entity, a second device model entity, and positional information corresponding to positions of the device model entities in a physical environment. Based on a physical linking rule that applies to the first device model entity and the second device model entity, and that defines one or more physical connections between the first device model entity and the second device model entity, the system generates one or more cabling entities that indicate one or more physical connections between physical devices represented by the device model entities. Based on the cabling entities and the positional information, the system outputs a set of one or more attributes for one or more physical cables that correspond to the cabling entities for use in a bill of materials.

### INCORPORATION BY REFERENCE; DISCLAIMER

Each of the following applications are hereby incorporated by reference: 63/771,165, filed Mar. 13, 2025. The Applicant hereby rescinds any disclaimer of claim scope in the parent application(s) or the prosecution history thereof and advises the USPTO that the claims in this application may be broader than any claim in the parent application(s).

### TECHNICAL FIELD

The present disclosure relates to cloud computing data centers. In particular, the present disclosure relates to modeling computing resources in a data center design to determine the physical cabling resources for use in a data center.

### BACKGROUND

A data center includes large numbers of computing and networking hardware components. A data center may have hundreds of thousands or millions of physical cabling connections between components in the data center. Furthermore, the physical cables are preferably long enough to make an expected connection while not being longer than needed. Physical cables that are longer than needed for a given connection may experience more signal loss compared to shorter cables. Longer cables may be associated with a higher cost than shorter cables. Physical cables of specific lengths and types are preferably ordered in advance of receiving and installing the physical computing components in the data center.

The approaches described in this section are approaches that could be pursued, but not necessarily approaches that have been previously conceived or pursued. Therefore, unless otherwise indicated, one should not assume that any of the approaches described in this section qualify as prior art merely by virtue of their inclusion in this section.

### BRIEF DESCRIPTION OF DRAWINGS

The embodiments are illustrated by way of example and not by way of limitation in the figures of the accompanying drawings. References to “an” or “one” embodiment in this disclosure are not necessarily to the same embodiment, and they mean at least one. In the drawings:

FIG. 1 is a block diagram illustrating one pattern for implementing a cloud infrastructure as a service system in accordance with one or more embodiments;

FIG. 2 is a block diagram illustrating another pattern for implementing a cloud infrastructure as a service system in accordance with one or more embodiments;

FIG. 3 is a block diagram illustrating another pattern for implementing a cloud infrastructure as a service system in accordance with one or more embodiments;

FIG. 4 is a block diagram illustrating another pattern for implementing a cloud infrastructure as a service system in accordance with one or more embodiments;

FIG. 5 is a high-level diagram of a distributed environment showing a virtual or overlay cloud network hosted by a cloud service provider infrastructure in accordance with one or more embodiments;

FIG. 6 depicts a simplified architectural diagram of the physical components in the physical network within CI in accordance with one or more embodiments;

FIG. 7 depicts a simplified block diagram of a physical network provided by a CI in accordance with one or more embodiments;

FIG. 8 depicts a data center containing rows of compute racks and network racks, with the network racks implementing a network fabric in accordance with one or more embodiments;

FIG. 9 depicts a block diagram that illustrates a computer system in accordance with one or more embodiments;

FIG. 10 illustrates a system in accordance with one or more embodiments;

FIG. 11 illustrates an example set of operations for determining physical cabling resources for a data center based on a data center model in accordance with one or more embodiments;

FIG. 12A illustrates a representation of logical components in a data center model in accordance with one or more embodiments;

FIG. 12B is a block diagram illustrating an example of a physical connection between devices in a data center;

FIG. 13A illustrates a representation of positional information for a data center model in accordance with one or more embodiments; and

FIG. 13B illustrates a representation of a layout model in accordance with one or more embodiments.

### DETAILED DESCRIPTION

### Introduction

In the following description, for the purposes of explanation, numerous specific details are set forth to provide a thorough understanding. One or more embodiments may be practiced without these specific details. Features described in one embodiment may be combined with features described in a different embodiment. In some examples, well-known structures and devices are described with reference to a block diagram form to avoid unnecessarily obscuring the present disclosure.

The term “cloud computing service” or “cloud service” is generally used to refer to a service that is made available by a cloud services provider (CSP) to users or customers on demand (e.g., via a subscription model) using systems and infrastructure (cloud infrastructure) provided by the CSP.

In most cases, the CSP is a third-party service that specializes in providing (e.g., offering, renting, selling) cloud services to customers. The servers and systems that make up the CSP's infrastructure are separate from the customer's own on-premises servers and systems. Customers can thus avail themselves of cloud services provided by the CSP without having to purchase separate hardware and software resources for the services. Cloud services are designed to provide a subscribing customer easy, scalable access to applications and computing resources without the customer having to invest in procuring the infrastructure that is used for providing the services. In some instances, an entity might opt to deploy a private cloud, becoming its own provider of cloud services. In some instances, an entity may utilize both a private cloud and a public cloud provided by a third-party CSP, thereby forming a hybrid cloud.

There are several cloud service providers that offer various types of cloud services. There are various different types or models of cloud services including Software-as-a-Service (SaaS), Platform-as-a-Service (PaaS), Infrastructure-as-a-Service (IaaS), and others. In an IaaS model, the CSP provides infrastructure (referred to as “cloud services provider infrastructure” or “CSPI”) that can be used by customers to build their own customizable networks and deploy customer resources.

A customer can subscribe to one or more cloud services provided by a CSP. The customer can be any entity, and the like. When a customer subscribes to or registers for a service provided by a CSP, a tenancy, or an account, is created for that customer. The customer can then, via this account, access the subscribed-to one or more cloud resources associated with the account.
1. GENERAL OVERVIEW
2. EXAMPLES OF CLOUD INFRASTRUCTURE
3. EXAMPLES OF CLOUD NETWORKS
4. EXAMPLE NETWORK FABRICS
5. HARDWARE OVERVIEW
6. CABLING DETERMINATION ARCHITECTURE
7. DETERMINING PHYSICAL CABLING RESOURCES FOR A DATA CENTER BASED ON A DATA CENTER MODEL
8. EXAMPLE EMBODIMENT
9. PRACTICAL APPLICATIONS, ADVANTAGES, AND IMPROVEMENTS
10. MISCELLANEOUS; EXTENSIONS

### 1. General Overview

A data center model includes device model entities that represent device models, linking entities representing connections between pairs of device model entities and linking rules that indicate how two physical devices, represented by device model entities, are to be connected. The data center model includes positional information that indicates where a device will be placed in the physical environment of the data center. The data center model includes physical linking rules that define one or more physical connections between device model entities.

One or more embodiments determine the physical cabling resources needed to implement physical connections in a data center based on the data center model. Initially, the system executes operations to determine the cabling resources needed to physically implement a connection between two device instances that are represented by two device model entities. Based on a physical linking rule that applies to a first device model entity and a second device model entity, the system generates one or more cabling entities, indicating one or more physical connections between physical devices represented respectively by the two device model entities. Based on the cabling entities and the positional information, the system outputs a set of one or more attributes for one or more physical cables, corresponding to the cabling entities for use in a bill of materials.

One or more embodiments described in this Specification and/or recited in the claims may not be included in this General Overview section.

### 2. Examples of Cloud Infrastructure

The term “cloud computing service” or “cloud service” generally refers to a service that is made available on demand, via scalable cloud infrastructure, typically over the internet or a private network, and managed by an external or in-house cloud provider (CP). The term “cloud infrastructure” (CI) generally refers to hardware and software components that provide computing, storage, and networking resources to deliver cloud services. There are various types or models of cloud services including Software-as-a-Service (SaaS), Platform-as-a-Service (PaaS), Infrastructure-as-a-Service (IaaS), Function-as-a-Service (FaaS), and others.

In a typical IaaS model, a CP provides virtualized and bare metal computing resources like servers, storage, and networking in a CP-operated data center. The CP is responsible for managing and maintaining the CI; the responsibilities span across multiple domains, such as operations, security, scalability, and compliance. Customers access the cloud services over the public Internet. Customers can use the CP CI to build their own customizable virtual or overlay networks and deploy customer resources. In other models, a CP provides similar virtualized and bare metal computing resources but in a customer-operated data center, which may include the customer's own CI. Customers access the CP CI and the customer CI over a private network. The combination of cloud services of the CP and the customer may be referred to as a “hybrid cloud.” In some cases, customers can serve as the CP's partner and sell the CP cloud services to further downstream customers. In yet other models, a first CP provides its virtualized and bare metal computing resources like servers, storage, and networking in the first CP's data center. A second CP provides its virtualized and bare metal computing resources also in the first CP's data center. A dedicated private network connects the CI of the two CPs. The combination of cloud services of both CPs may be referred to as a “hybrid cloud.” In yet other models, a CP initially provisions CI to a customer, and then hands over all or a subset of the responsibilities associated with managing and maintaining the CI. For example, the customer may be primarily responsible for duties such as provisioning, repair, and maintenance of compute instances, while the CP retains other duties such as network management. Still other models may be used.

As noted above, infrastructure as a service (IaaS) is one particular type of cloud computing. For IaaS, the infrastructure (CI) provided by a CP can be configured to provide virtualized computing resources over a public network (e.g., the Internet). In an IaaS model, a CP can host the infrastructure components (e.g., servers, storage devices, network nodes (e.g., hardware), deployment software, platform virtualization (e.g., a hypervisor layer), or the like). CI thus provides infrastructure and a set of complementary cloud services that enable customers to build and run a wide range of applications and services in a highly available hosted distributed environment. The customer does not manage or control the underlying physical resources provided by CI but has control over operating systems, storage, and deployed applications; and possibly limited control of select networking components (e.g., firewalls).

In some cases, an IaaS provider may also supply a variety of services to accompany those infrastructure components (example services include billing software, monitoring software, logging software, load balancing software, clustering software, etc.). Thus, as these services may be policy-driven, IaaS users may be able to implement policies to drive load balancing to maintain application availability and performance. When a customer subscribes to or registers for an IaaS service provided by a CP, a tenancy, or account, is created for the customer. A tenancy is a secure and isolated partition within the CI where the customer can create, organize, and administer their cloud resources.

In some instances, IaaS customers may access resources and services through a wide area network (WAN), such as the Internet, and can use the cloud provider's services to install the remaining elements of an application stack. For example, the user can log in to the IaaS platform to create virtual machines (VMs), install operating systems (OSs) on each VM, deploy middleware such as databases, create storage buckets for workloads and backups, and even install enterprise software into that VM. Customers can then use the provider's services to perform various functions, including balancing network traffic, troubleshooting application issues, monitoring performance, managing disaster recovery, etc.

The CP may provide a console that enables customers and network administrators to configure, access, and manage resources deployed in the cloud using CI resources. In certain embodiments, the console provides a web-based user interface that can be used to access and manage CI. In some implementations, the console is a web-based application provided by the CP.

CI may support single-tenancy or multi-tenancy architectures. In a single tenancy architecture, a software (e.g., an application, a database) or a hardware component (e.g., a host machine or a server) of the CI serves a single customer or tenant. In a multi-tenancy architecture, a software or a hardware component of the CI serves multiple customers or tenants. Thus, in a multi-tenancy architecture, CI resources are shared between multiple customers or tenants. In a multi-tenancy situation, precautions are taken, and safeguards put in place within CI to ensure that each tenant's data is isolated and remains invisible to other tenants.

In certain embodiments, cloud resources within CI may include, for example, compute instances, block storage volumes, virtual cloud networks (VCNs), subnets, databases, third-party applications, SaaS applications, on-premises software, and web applications. Each cloud resource is assigned a unique identifier called a Cloud Identifier (CID). This identifier is included as part of the resource's information and can be used to manage the resource, for example, via a Console or through APIs. An example syntax for a CID is:
cid1.<RESOURCE TYPE>.<REALM>. [REGION][.FUTURE USE].<UNIQUE ID>
where,
cid1: The literal string indicating the version of the CID;
resource type: The type of resource (for example, instance, volume, VCN, subnet, user, group, and so on);
realm: The realm the resource is in. Example values are “c1” for the commercial realm, “c2” for the Government Cloud realm, or “c3” for the Federal Government Cloud realm, etc. Each realm may have its own domain name;
region: The region the resource is in. If the region is not applicable to the resource, this part might be blank;
future use: Reserved for future use.
unique ID: The unique portion of the ID. The format may vary depending on the type of resource or service.

In some examples, IaaS deployment is the process of putting a new application, or a new version of an application, onto a prepared application server or the like. It may also include the process of preparing the server (e.g., installing libraries, daemons, etc.). This is often managed by the cloud provider, below the hypervisor layer (e.g., the servers, storage, network hardware, and virtualization). Thus, the customer may be responsible for handling (OS), middleware, and/or application deployment (e.g., on self-service virtual machines (e.g., that can be spun up on demand) or the like.

In some examples, IaaS provisioning may refer to acquiring computers or virtual hosts for use, and even installing needed libraries or services on them. In most cases, deployment does not include provisioning, and the provisioning may need to be performed first.

In some cases, there are two different challenges for IaaS provisioning. First, there is the initial challenge of provisioning the initial set of infrastructure before anything is running. Second, there is the challenge of evolving the existing infrastructure (e.g., adding new services, changing services, removing services, etc.) once everything has been provisioned. In some cases, these two challenges may be addressed by enabling the configuration of the infrastructure to be defined declaratively. In other words, the infrastructure (e.g., what components are needed and how they interact) can be defined by one or more configuration files. Thus, the overall topology of the infrastructure (e.g., what resources depend on which, and how they each work together) can be described declaratively. In some instances, once the topology is defined, a workflow can be generated that creates and/or manages the different components described in the configuration files.

In some examples, an infrastructure may have many interconnected elements. For example, there may be one or more virtual private clouds (VPCs) (e.g., a potentially on-demand pool of configurable and/or shared computing resources), also known as a core network. In some examples, there may also be one or more inbound/outbound traffic group rules provisioned to define how the inbound and/or outbound traffic of the network will be set up and one or more virtual machines (VMs). Other infrastructure elements may also be provisioned, such as a load balancer, a database, or the like. As more and more infrastructure elements are desired and/or added, the infrastructure may incrementally evolve.

In some instances, continuous deployment techniques may be employed to enable deployment of infrastructure code across various virtual computing environments. Additionally, the described techniques can enable infrastructure management within these environments. In some examples, service teams can write code that is desired to be deployed to one or more, but often many, different production environments (e.g., across various different geographic locations, sometimes spanning the entire world). However, in some examples, the infrastructure on which the code will be deployed must first be set up. In some instances, the provisioning can be done manually, a provisioning tool may be utilized to provision the resources, and/or deployment tools may be utilized to deploy the code once the infrastructure is provisioned.

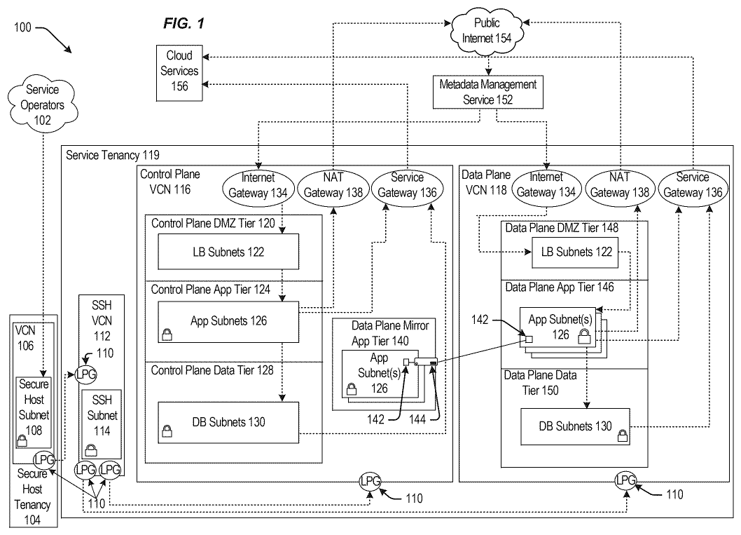

FIG. 1 is a block diagram illustrating an example pattern of an IaaS architecture 100 according to at least one embodiment. Service operators 102 can be communicatively coupled to a secure host tenancy 104 that can include a virtual cloud network (VCN) 106 and a secure host subnet 108. In some examples, the service operators 102 may be using one or more client computing devices, such as portable handheld devices (e.g., an iPhone®, cellular telephone, an iPad®, computing tablet, a personal digital assistant (PDA)) or wearable devices (e.g., a Google Glass® head mounted display), executing software, such as Microsoft Windows Mobile®, and/or a variety of mobile operating systems, such as iOS, Windows Phone, Android, BlackBerry 8, Palm OS, and the like, and be Internet, e-mail, short message service (SMS), Blackberry®, or other communication protocol enabled. Alternatively, the client computing devices can be general purpose personal computers, including personal computers and/or laptop computers that are executing various versions of Microsoft Windows®, Apple Macintosh®, and/or Linux operating systems. The client computing devices can be workstation computers executing any of a variety of commercially available UNIX® or UNIX-like operating systems that include, for example, GNU/Linux operating systems and Google Chrome OS. Additionally, or alternatively, client computing devices may be any other electronic device, such as a thin-client computer, an Internet-enabled gaming system (e.g., a Microsoft Xbox gaming console with or without a Kinect® gesture input device), and/or a personal messaging device, capable of communicating over a network that can access the VCN 106 and/or the Internet.

The VCN 106 can include a local peering gateway (LPG) 110 that can be communicatively coupled to a secure shell (SSH) VCN 112 via an LPG 110 implemented in the SSH VCN 112. The SSH VCN 112 can include an SSH subnet 114, and the SSH VCN 112 can be communicatively coupled to a control plane VCN 116 via the LPG 110 implemented in the control plane VCN 116. Also, the SSH VCN 112 can be communicatively coupled to a data plane VCN 118 via an LPG 110. The control plane VCN 116 and the data plane VCN 118 can be implemented in a service tenancy 119 that can be owned and/or operated by the IaaS provider.

The control plane VCN 116 can include a control plane demilitarized zone (DMZ) tier 120 that acts as a perimeter network (e.g., portions of a corporate network between the corporate intranet and external networks). The DMZ-based servers may have restricted responsibilities and help keep breaches contained. Additionally, the DMZ tier 120 can include one or more load balancer (LB) subnet(s) 122, a control plane app tier 124 that can include app subnet(s) 126, a control plane data tier 128 that can include database (DB) subnet(s) 130 (e.g., frontend DB subnet(s) and/or backend DB subnet(s)). The LB subnet(s) 122 in the control plane DMZ tier 120 can be communicatively coupled to the app subnet(s) 126 in the control plane app tier 124 and an Internet gateway 134 that can be implemented in the control plane VCN 116. The app subnet(s) 126 can be communicatively coupled to the DB subnet(s) 130 implemented in the control plane data tier 128 and a service gateway 136 and a network address translation (NAT) gateway 138. The control plane VCN 116 can include the service gateway 136 and the NAT gateway 138.

The control plane VCN 116 can include a data plane mirror app tier 140 that can include app subnet(s) 126. The app subnet(s) 126 implemented in the data plane mirror app tier 140 can include a virtual network interface controller (VNIC) 142 that can execute a compute instance 144. The compute instance 144 can communicatively couple the app subnet(s) 126 of the data plane mirror app tier 140 to app subnet(s) 126 that can be implemented in a data plane app tier 146.

The data plane VCN 118 can include the data plane app tier 146, a data plane DMZ tier 148, and a data plane data tier 150. The data plane DMZ tier 148 can include LB subnet(s) 122 that can be communicatively coupled to the app subnet(s) 126 of the data plane app tier 146 and the Internet gateway 134 of the data plane VCN 118. The app subnet(s) 126 can be communicatively coupled to the service gateway 136 of the data plane VCN 118 and the NAT gateway 138 of the data plane VCN 118. The data plane data tier 150 can also include the DB subnet(s) 130 that can be communicatively coupled to the app subnet(s) 126 of the data plane app tier 146.

The Internet gateway 134 of the control plane VCN 116 and of the data plane VCN 118 can be communicatively coupled to a metadata management service 152 that can be communicatively coupled to public Internet 154. Public Internet 154 can be communicatively coupled to the NAT gateway 138 of the control plane VCN 116 and of the data plane VCN 118. The service gateway 136 of the control plane VCN 116 and of the data plane VCN 118 can be communicatively couple to cloud services 156.

In some examples, the service gateway 136 of the control plane VCN 116 or of the data plane VCN 118 can make application programming interface (API) calls to cloud services 156 without going through public Internet 154. The API calls to cloud services 156 from the service gateway 136 can be one-way; the service gateway 136 can make API calls to cloud services 156, and cloud services 156 can send requested data to the service gateway 136. However, cloud services 156 may not initiate API calls to the service gateway 136.

In some examples, the secure host tenancy 104 can be directly connected to the service tenancy 119. The service tenancy 119 may otherwise be isolated. The secure host subnet 108 can communicate with the SSH subnet 114 through an LPG 110 that may enable two-way communication over an otherwise isolated system. Connecting the secure host subnet 108 to the SSH subnet 114 may give the secure host subnet 108 access to other entities within the service tenancy 119.

The control plane VCN 116 may allow users of the service tenancy 119 to set up or otherwise provision resources. Resources provisioned in the control plane VCN 116 may be deployed or otherwise used in the data plane VCN 118. In some examples, the control plane VCN 116 can be isolated from the data plane VCN 118, and the data plane mirror app tier 140 of the control plane VCN 116 can communicate with the data plane app tier 146 of the data plane VCN 118 via VNICs 142 that can be implemented in the data plane mirror app tier 140 and the data plane app tier 146.

In some examples, users or customers, of the system, can make requests, for example create, read, update, or delete (CRUD) operations, through public Internet 154 that can communicate the requests to the metadata management service 152. The metadata management service 152 can communicate the request to the control plane VCN 116 through the Internet gateway 134. The request can be received by the LB subnet(s) 122 implemented in the control plane DMZ tier 120. The LB subnet(s) 122 may determine that the request is valid, and in response, the LB subnet(s) 122 can transmit the request to app subnet(s) 126 implemented in the control plane app tier 124. If the request is validated and requires a call to public Internet 154, the call to public Internet 154 may be transmitted to the NAT gateway 138 that can make the call to public Internet 154. Metadata to be stored by the request can be stored in the DB subnet(s) 130.

In some examples, the data plane mirror app tier 140 can facilitate direct communication between the control plane VCN 116 and the data plane VCN 118. For example, changes, updates, or other suitable modifications to a configuration may need to be applied to the resources implemented in the data plane VCN 118. Via a VNIC 142, the control plane VCN 116 can directly communicate with, and can thereby execute the changes, updates, or other suitable modifications to configuration to, resources implemented in the data plane VCN 118.

In some embodiments, the control plane VCN 116 and the data plane VCN 118 can be implemented in the service tenancy 119. In this case, the user, or the customer, of the system may not own or operate either the control plane VCN 116 or the data plane VCN 118. Instead, the IaaS provider may own or operate the control plane VCN 116 and the data plane VCN 118. The control plane VCN 116 and the data plane VCN 118 may be implemented in the service tenancy 119. This embodiment can enable isolation of networks that may prevent users or customers from interacting with other users', or other customers', resources. Also, this embodiment may allow users, or customers, of the system to store databases privately without needing to rely on public Internet 154 for storage.

In other embodiments, the LB subnet(s) 122 implemented in the control plane VCN 116 can be configured to receive a signal from the service gateway 136. In this embodiment, the control plane VCN 116 and the data plane VCN 118 may be configured to be called by a customer of the IaaS provider without calling public Internet 154. Customers of the IaaS provider may need this embodiment since database(s) that the customers use may be controlled by the IaaS provider and may be stored on the service tenancy 119. The service tenancy 119 may be isolated from public Internet 154.

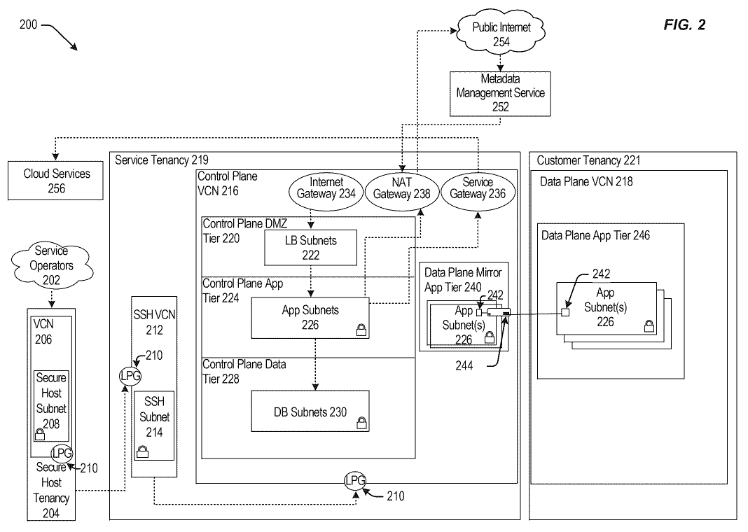

FIG. 2 is a block diagram illustrating another example pattern of an IaaS architecture 2 according to at least one embodiment. Service operators 202 (e.g., service operators 102 of FIG. 1) can be communicatively coupled to a secure host tenancy 204 (e.g., the secure host tenancy 104 of FIG. 1) that can include a virtual cloud network (VCN) 206 (e.g., the VCN 106 of FIG. 1) and a secure host subnet 208 (e.g., the secure host subnet 108 of FIG. 1). The VCN 206 can include a local peering gateway (LPG) 210 (e.g., the LPG 110 of FIG. 1) that can be communicatively coupled to a secure shell (SSH) VCN 212 (e.g., the SSH VCN 112 of FIG. 1) via an LPG 210 implemented in the SSH VCN 212. The SSH VCN 212 can include an SSH subnet 214 (e.g., the SSH subnet 114 of FIG. 1), and the SSH VCN 212 can be communicatively coupled to a control plane VCN 216 (e.g., the control plane VCN 116 of FIG. 1) via an LPG 210 implemented in the control plane VCN 216. The control plane VCN 216 can be implemented in a service tenancy 219 (e.g., the service tenancy 119 of FIG. 1), and the data plane VCN 218 (e.g., the data plane VCN 118 of FIG. 1) can be implemented in a customer tenancy 221 that may be owned or operated by users, or customers, of the system.

The control plane VCN 216 can include a control plane DMZ tier 220 (e.g., the control plane DMZ tier 120 of FIG. 1) that can include LB subnet(s) 222 (e.g., LB subnet(s) 122 of FIG. 1), a control plane app tier 224 (e.g., the control plane app tier 124 of FIG. 1) that can include app subnet(s) 226 (e.g., app subnet(s) 126 of FIG. 1), and a control plane data tier 228 (e.g., the control plane data tier 128 of FIG. 1) that can include database (DB) subnet(s) 230 (e.g., similar to DB subnet(s) 130 of FIG. 1). The LB subnet(s) 222 implemented in the control plane DMZ tier 220 can be communicatively coupled to the app subnet(s) 226 implemented in the control plane app tier 224 and an Internet gateway 234 (e.g., the Internet gateway 134 of FIG. 1) that can be implemented in the control plane VCN 216. The app subnet(s) 226 can be communicatively coupled to the DB subnet(s) 230 implemented in the control plane data tier 228 and a service gateway 236 (e.g., the service gateway 136 of FIG. 1) and a network address translation (NAT) gateway 238 (e.g., the NAT gateway 138 of FIG. 1). The control plane VCN 216 can include the service gateway 236 and the NAT gateway 238.

The control plane VCN 216 can include a data plane mirror app tier 240 (e.g., the data plane mirror app tier 140 of FIG. 1) that can include app subnet(s) 226. The app subnet(s) 226 implemented in the data plane mirror app tier 240 can include a virtual network interface controller (VNIC) 242 (e.g., the VNIC of 142) that can execute a compute instance 244 (e.g., similar to the compute instance 144 of FIG. 1). The compute instance 244 can facilitate communication between the app subnet(s) 226 of the data plane mirror app tier 240 and the app subnet(s) 226 that can be implemented in a data plane app tier 246 (e.g., the data plane app tier 146 of FIG. 1). The compute instance 244 can facilitate this communication via the VNIC 242 implemented in the data plane mirror app tier 240 and the VNIC 242 implemented in the data plane app tier 246.

The Internet gateway 234 implemented in the control plane VCN 216 can be communicatively coupled to a metadata management service 252 (e.g., the metadata management service 152 of FIG. 1) that can be communicatively coupled to public Internet 254 (e.g., public Internet 154 of FIG. 1). Public Internet 254 can be communicatively coupled to the NAT gateway 238 implemented in the control plane VCN 216. The service gateway 236 implemented in the control plane VCN 216 can be communicatively couple to cloud services 256 (e.g., cloud services 156 of FIG. 1).

In some examples, the data plane VCN 218 can be implemented in the customer tenancy 221. In this case, the IaaS provider may provide the control plane VCN 216 for a customer, and the IaaS provider may, for a customer, set up a unique, compute instance 244 that is implemented in the service tenancy 219. A compute instance 244 may allow communication between the control plane VCN 216 implemented in the service tenancy 219 and the data plane VCN 218 that is implemented in the customer tenancy 221. The compute instance 244 may allow resources provisioned in the control plane VCN 216 that is implemented in the service tenancy 219 to be deployed or otherwise used in the data plane VCN 218 that is implemented in the customer tenancy 221.

In other examples, the customer of the IaaS provider may have databases that are implemented in the customer tenancy 221. In this example, the control plane VCN 216 can include the data plane mirror app tier 240 that can include app subnet(s) 226. The data plane mirror app tier 240 can be implemented in the control plane VCN 216, but the data plane mirror app tier 240 may not be implemented in the data plane VCN 218. That is, the data plane mirror app tier 240 may have access to the customer tenancy 221, but the data plane mirror app tier 240 may not exist in the data plane VCN 218 or be owned or operated by the customer of the IaaS provider. The data plane mirror app tier 240 may be configured to make calls to the data plane VCN 218 but may not be configured to make calls to any entity implemented in the control plane VCN 216. The customer may need to deploy or otherwise use resources in the data plane VCN 218 that are provisioned in the control plane VCN 216, and the data plane mirror app tier 240 can facilitate the deployment or other usage of resources of the customer.

In some embodiments, the customer of the IaaS provider can apply filters to the data plane VCN 218. In this embodiment, the customer can determine what the data plane VCN 218 can access, and the customer may restrict access to public Internet 254 from the data plane VCN 218. The IaaS provider may not be able to apply filters or otherwise control access of the data plane VCN 218 to any outside networks or databases. Applying filters and controls by the customer onto the data plane VCN 218, implemented in the customer tenancy 221, can help isolate the data plane VCN 218 from other customers and from public Internet 254.

In some embodiments, cloud services 256 can be called by the service gateway 236 to access services that may not exist on public Internet 254, on the control plane VCN 216, or on the data plane VCN 218. The connection between cloud services 256 and the control plane VCN 216 or the data plane VCN 218 may not be active or continuous. Cloud services 256 may exist on a different network owned or operated by the IaaS provider. Cloud services 256 may be configured to receive calls from the service gateway 236 and may be configured to not receive calls from public Internet 254. Some cloud services 256 may be isolated from other cloud services 256, and the control plane VCN 216 may be isolated from cloud services 256 that may not be in the same region as the control plane VCN 216. For example, the control plane VCN 216 may be located in “Region 1,” and cloud service “Deployment 1” may be located in Region 1 and in “Region 2.” If a call to Deployment 1 is made by the service gateway 236 implemented in the control plane VCN 216 located in Region 1, the call may be transmitted to Deployment 1 in Region 1. In this example, the control plane VCN 216, or Deployment 1 in Region 1, may not be communicatively coupled to, or otherwise in communication with, Deployment 1 in Region 2.

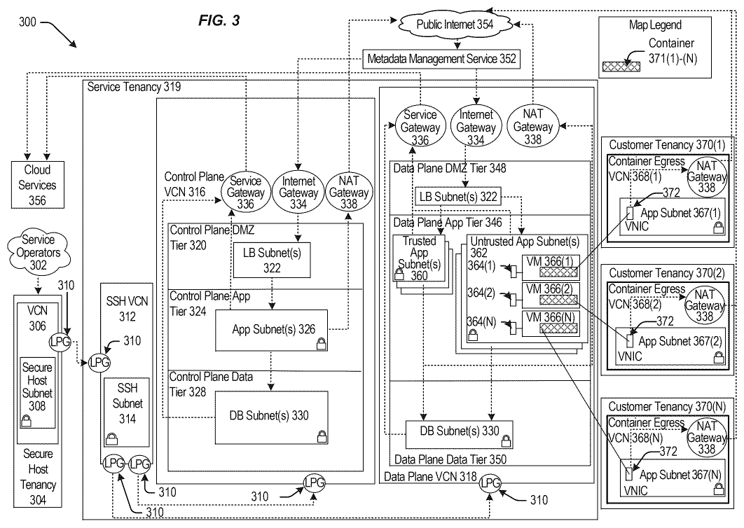

FIG. 3 is a block diagram illustrating another example pattern of an IaaS architecture 300 according to at least one embodiment. Service operators 302 (e.g., service operators 102 of FIG. 1) can be communicatively coupled to a secure host tenancy 304 (e.g., the secure host tenancy 104 of FIG. 1) that can include a virtual cloud network (VCN) 306 (e.g., the VCN 106 of FIG. 1) and a secure host subnet 308 (e.g., the secure host subnet 108 of FIG. 1). The VCN 306 can include an LPG 310 (e.g., the LPG 110 of FIG. 1) that can be communicatively coupled to an SSH VCN 312 (e.g., the SSH VCN 112 of FIG. 1) via an LPG 310 implemented in the SSH VCN 312. The SSH VCN 312 can include an SSH subnet 314 (e.g., the SSH subnet 114 of FIG. 1), and the SSH VCN 312 can be communicatively coupled to a control plane VCN 316 (e.g., the control plane VCN 116 of FIG. 1) via an LPG 310 implemented in the control plane VCN 316 and to a data plane VCN 318 (e.g., the data plane VCN 118 of FIG. 1) via an LPG 310 implemented in the data plane VCN 318. The control plane VCN 316 and the data plane VCN 318 can be implemented in a service tenancy 319 (e.g., the service tenancy 119 of FIG. 1).

The control plane VCN 316 can include a control plane DMZ tier 320 (e.g., the control plane DMZ tier 120 of FIG. 1) that can include load balancer (LB) subnet(s) 322 (e.g., LB subnet(s) 122 of FIG. 1), a control plane app tier 324 (e.g., the control plane app tier 124 of FIG. 1) that can include app subnet(s) 326 (e.g., similar to app subnet(s) 126 of FIG. 1), and a control plane data tier 328 (e.g., the control plane data tier 128 of FIG. 1) that can include DB subnet(s) 330. The LB subnet(s) 322 implemented in the control plane DMZ tier 320 can be communicatively coupled to the app subnet(s) 326 implemented in the control plane app tier 324 and to an Internet gateway 334 (e.g., the Internet gateway 134 of FIG. 1) that can be implemented in the control plane VCN 316, and the app subnet(s) 326 can be communicatively coupled to the DB subnet(s) 330 implemented in the control plane data tier 328 and to a service gateway 336 (e.g., the service gateway of FIG. 1) and a network address translation (NAT) gateway 338 (e.g., the NAT gateway 138 of FIG. 1). The control plane VCN 316 can include the service gateway 336 and the NAT gateway 338.

The data plane VCN 318 can include a data plane app tier 346 (e.g., the data plane app tier 146 of FIG. 1), a data plane DMZ tier 348 (e.g., the data plane DMZ tier 148 of FIG. 1), and a data plane data tier 350 (e.g., the data plane data tier 150 of FIG. 1). The data plane DMZ tier 348 can include LB subnet(s) 322 that can be communicatively coupled to trusted app subnet(s) 360, untrusted app subnet(s) 362 of the data plane app tier 346, and the Internet gateway 334 implemented in the data plane VCN 318. The trusted app subnet(s) 360 can be communicatively coupled to the service gateway 336 implemented in the data plane VCN 318, the NAT gateway 338 implemented in the data plane VCN 318, and DB subnet(s) 330 implemented in the data plane data tier 350. The untrusted app subnet(s) 362 can be communicatively coupled to the service gateway 336 implemented in the data plane VCN 318 and DB subnet(s) 330 implemented in the data plane data tier 350. The data plane data tier 350 can include DB subnet(s) 330 that can be communicatively coupled to the service gateway 336 implemented in the data plane VCN 318.

The untrusted app subnet(s) 362 can include one or more primary VNICs 364(1)-(N) that can be communicatively coupled to tenant virtual machines (VMs) 366(1)-(N). Tenant VMs 366(1)-(N) can be communicatively coupled to a respective app subnets 367(1)-(N) that can be implemented in respective container egress VCNs 368(1)-(N) that can be implemented in respective customer tenancies 370(1)-(N). Respective secondary VNICs 372(1)-(N) can facilitate communication between the untrusted app subnet(s) 362 implemented in the data plane VCN 318 and the app subnet implemented in the container egress VCNs 368(1)-(N). Container egress VCNs 368(1)-(N) can include a NAT gateway 338 that can be communicatively coupled to public Internet 354 (e.g., public Internet 154 of FIG. 1).

The Internet gateway 334 implemented in the control plane VCN 316 and implemented in the data plane VCN 318 can be communicatively coupled to a metadata management service 352 (e.g., the metadata management service 152 of FIG. 1) that can be communicatively coupled to public Internet 354. Public Internet 354 can be communicatively coupled to the NAT gateway 338 implemented in the control plane VCN 316 and implemented in the data plane VCN 318. The service gateway 336 implemented in the control plane VCN 316 and implemented in the data plane VCN 318 can be communicatively couple to cloud services 356.

In some embodiments, the data plane VCN 318 can be integrated with customer tenancies 370(1)-(N). This integration can be useful or needed for customers of the IaaS provider in some cases such as a case that may need support when executing code. The customer may provide code to execute that may be destructive, may communicate with other customer resources, or may otherwise cause undesirable effects. In response to this, the IaaS provider may determine whether or not to execute code given to the IaaS provider by the customer.

In some examples, the customer of the IaaS provider may grant temporary network access to the IaaS provider and request a function to be attached to the data plane app tier 346. Code to execute the function may be executed in the VMs 366(1)-(N), and the code may not be configured to execute anywhere else on the data plane VCN 318. VMs 366(1)-(N) may be connected to one customer tenancy 370(1). Respective containers 371(1)-(N) implemented in the VMs 366(1)-(N) may be configured to execute the code. In this case, there can be a dual isolation (e.g., the containers 371(1)-(N) executing code), where the containers 371(1)-(N) may be implemented in at least the VM 366(1)-(N) that are implemented in the untrusted app subnet(s) 362) that may help prevent incorrect or otherwise undesirable code from damaging the network of the IaaS provider or from damaging a network of a different customer. The containers 371(1)-(N) may be communicatively coupled to the customer tenancy 370 and may be configured to transmit or receive data from the customer tenancy 370. The containers 371(1)-(N) may not be configured to transmit or receive data from any other entity in the data plane VCN 318. Upon completing execution of the code, the IaaS provider may terminate or otherwise dispose of the containers 371(1)-(N).

In some embodiments, the trusted app subnet(s) 360 may execute code that may be owned or operated by the IaaS provider. In this embodiment, the trusted app subnet(s) 360 may be communicatively coupled to the DB subnet(s) 330 and be configured to execute CRUD operations in the DB subnet(s) 330. The untrusted app subnet(s) 362 may be communicatively coupled to the DB subnet(s) 330, but in this embodiment, the untrusted app subnet(s) may be configured to execute read operations in the DB subnet(s) 330. The containers 371(1)-(N) that can be implemented in the VM 366(1)-(N) of a customer and that may execute code from the customer may not be communicatively coupled with the DB subnet(s) 330.

In other embodiments, the control plane VCN 316 and the data plane VCN 318 may not be directly communicatively coupled. In this embodiment, there may be no direct communication between the control plane VCN 316 and the data plane VCN 318. However, communication can occur indirectly through at least one method. An LPG 310 may be established by the IaaS provider that can facilitate communication between the control plane VCN 316 and the data plane VCN 318. In another example, the control plane VCN 316 or the data plane VCN 318 can make a call to cloud services 356 via the service gateway 336. For example, a call to cloud services 356 from the control plane VCN 316 can include a request for a service that can communicate with the data plane VCN 318.

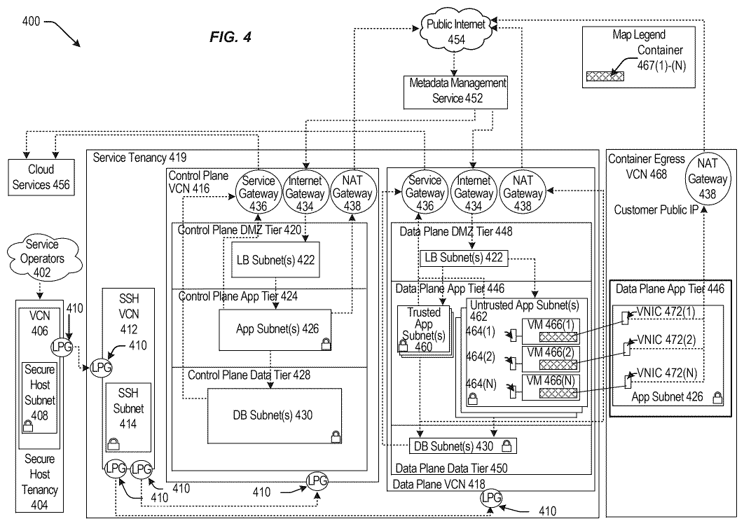

FIG. 4 is a block diagram illustrating another example pattern of an IaaS architecture 400 according to at least one embodiment. Service operators 402 (e.g., service operators 102 of FIG. 1) can be communicatively coupled to a secure host tenancy 404 (e.g., the secure host tenancy 104 of FIG. 1) that can include a virtual cloud network (VCN) 406 (e.g., the VCN 106 of FIG. 1) and a secure host subnet 408 (e.g., the secure host subnet 108 of FIG. 1). The VCN 406 can include an LPG 410 (e.g., the LPG 110 of FIG. 1) that can be communicatively coupled to an SSH VCN 412 (e.g., the SSH VCN 112 of FIG. 1) via an LPG 410 implemented in the SSH VCN 412. The SSH VCN 412 can include an SSH subnet 414 (e.g., the SSH subnet 114 of FIG. 1), and the SSH VCN 412 can be communicatively coupled to a control plane VCN 416 (e.g., the control plane VCN 116 of FIG. 1) via an LPG 410 implemented in the control plane VCN 416 and to a data plane VCN 418 (e.g., the data plane VCN 118 of FIG. 1) via an LPG 410 implemented in the data plane VCN 418. The control plane VCN 416 and the data plane VCN 418 can be implemented in a service tenancy 419 (e.g., the service tenancy 119 of FIG. 1).

The control plane VCN 416 can include a control plane DMZ tier 420 (e.g., the control plane DMZ tier 120 of FIG. 1) that can include LB subnet(s) 422 (e.g., LB subnet(s) 122 of FIG. 1), a control plane app tier 424 (e.g., the control plane app tier 124 of FIG. 1) that can include app subnet(s) 426 (e.g., app subnet(s) 126 of FIG. 1), and a control plane data tier 428 (e.g., the control plane data tier 128 of FIG. 1) that can include DB subnet(s) 430 (e.g., DB subnet(s) 330 of FIG. 3). The LB subnet(s) 422 implemented in the control plane DMZ tier 420 can be communicatively coupled to the app subnet(s) 426 implemented in the control plane app tier 424 and to an Internet gateway 434 (e.g., the Internet gateway 134 of FIG. 1) that can be implemented in the control plane VCN 416, and the app subnet(s) 426 can be communicatively coupled to the DB subnet(s) 430 implemented in the control plane data tier 428 and to a service gateway 436 (e.g., the service gateway of FIG. 1) and a network address translation (NAT) gateway 438 (e.g., the NAT gateway 138 of FIG. 1). The control plane VCN 416 can include the service gateway 436 and the NAT gateway 438.

The data plane VCN 418 can include a data plane app tier 446 (e.g., the data plane app tier 146 of FIG. 1), a data plane DMZ tier 448 (e.g., the data plane DMZ tier 148 of FIG. 1), and a data plane data tier 450 (e.g., the data plane data tier 150 of FIG. 1). The data plane DMZ tier 448 can include LB subnet(s) 422 that can be communicatively coupled to trusted app subnet(s) 460 (e.g., trusted app subnet(s) 360 of FIG. 3) and untrusted app subnet(s) 462 (e.g., untrusted app subnet(s) 362 of FIG. 3) of the data plane app tier 446 and the Internet gateway 434 implemented in the data plane VCN 418. The trusted app subnet(s) 460 can be communicatively coupled to the service gateway 436 implemented in the data plane VCN 418, the NAT gateway 438 implemented in the data plane VCN 418, and DB subnet(s) 430 implemented in the data plane data tier 450. The untrusted app subnet(s) 462 can be communicatively coupled to the service gateway 436 implemented in the data plane VCN 418 and DB subnet(s) 430 implemented in the data plane data tier 450. The data plane data tier 450 can include DB subnet(s) 430 that can be communicatively coupled to the service gateway 436 implemented in the data plane VCN 418.

The untrusted app subnet(s) 462 can include primary VNICs 464(1)-(N) that can be communicatively coupled to tenant virtual machines (VMs) 466(1)-(N) implemented within the untrusted app subnet(s) 462. Tenant VMs 466(1)-(N) can execute code in a respective container 467(1)-(N) and be communicatively coupled to an app subnet 467 that can be implemented in a data plane app tier 446 that can be implemented in a container egress VCN 468. Respective secondary VNICs 472(1)-(N) can facilitate communication between the untrusted app subnet(s) 462 implemented in the data plane VCN 418 and the app subnet 467 implemented in the container egress VCN 468. The container egress VCN 468 can include a NAT gateway 438 that can be communicatively coupled to public Internet 454 (e.g., public Internet 154 of FIG. 1).

The Internet gateway 434 implemented in the control plane VCN 416 and implemented in the data plane VCN 418 can be communicatively coupled to a metadata management service 452 (e.g., the metadata management service 152 of FIG. 1) that can be communicatively coupled to public Internet 454. Public Internet 454 can be communicatively coupled to the NAT gateway 438 implemented in the control plane VCN 416 and implemented in the data plane VCN 418. The service gateway 436 implemented in the control plane VCN 416 and implemented in the data plane VCN 418 can be communicatively couple to cloud services 456.

In some examples, the pattern illustrated by the architecture of block diagram 400 of FIG. 4 may be considered an exception to the pattern illustrated by the architecture of block diagram 300 of FIG. 3 and may be needed for a customer of the IaaS provider if the IaaS provider cannot directly communicate with the customer (e.g., a disconnected region). The respective containers 471(1)-(N) that are implemented in the VMs 466(1)-(N) for a customer can be accessed in real-time by the customer. The containers 471(1)-(N) may be configured to make calls to respective secondary VNICs 472(1)-(N) implemented in app subnet(s) 467 of the data plane app tier 446 that can be implemented in the container egress VCN 468. The secondary VNICs 472(1)-(N) can transmit the calls to the NAT gateway 438 that may transmit the calls to public Internet 454. In this example, the containers 471(1)-(N) that can be accessed in real time by the customer can be isolated from the control plane VCN 416 and can be isolated from other entities implemented in the data plane VCN 418. The containers 471(1)-(N) may also be isolated from resources from other customers.

In other examples, the customer can use the containers 471(1)-(N) to call cloud services 456. In this example, the customer may execute code in the containers 471(1)-(N) that request a service from cloud services 456. The containers 471(1)-(N) can transmit this request to the secondary VNICs 472(1)-(N) that can transmit the request to the NAT gateway 438 that can transmit the request to public Internet 454. Public Internet 454 can transmit the request to LB subnet(s) 422 implemented in the control plane VCN 416 via the Internet gateway 434. In response to determining the request is valid, the LB subnet(s) can transmit the request to app subnet(s) 426 that can transmit the request to cloud services 456 via the service gateway 436.

It should be appreciated that IaaS architectures 100, 200, 300, and 400 may include components that are different and/or additional to the components shown in the figures. Furthermore, the embodiments shown in the figures represent non-exhaustive examples of a cloud infrastructure system that may incorporate an embodiment of the disclosure. In some other embodiments, the IaaS systems may have more or fewer components than shown in the figures, may combine two or more components, or may have a different configuration or arrangement of components.

In certain embodiments, the IaaS systems described herein may include a suite of applications, middleware, and database service offerings that are delivered to a customer in a self-service, subscription-based, elastically scalable, reliable, highly available, and secure manner. An example of such an IaaS system is the Oracle Cloud Infrastructure (OCI) provided by the present assignee.

In one or more embodiments, a computer network provides connectivity among a set of nodes. A node may be local to and/or remote from another node. The nodes are connected by a set of links. Examples of links include a coaxial cable, an unshielded twisted cable, a copper cable, an optical fiber, and a virtual link.

A subset of nodes implements the computer network. Examples of such nodes include a switch, a router, a firewall, and a network address translator (NAT). Another subset of nodes uses the computer network. Such nodes (also referred to as “hosts”) may execute a client process and/or a server process. A client process makes a request for a computing service (such as execution of a particular application and/or storage of a particular amount of data). A server process responds by executing the requested service and/or returning corresponding data.

A computer network may be a physical network, including physical nodes connected by physical links. A physical node is any digital device. A physical node may be a function-specific hardware device, such as a hardware switch, a hardware router, a hardware firewall, and a hardware NAT. Additionally, or alternatively, a physical node may be a generic machine that is configured to execute various virtual machines and/or applications performing respective functions. A physical link is a physical medium connecting two or more physical nodes. Examples of links include a coaxial cable, an unshielded twisted cable, a copper cable, and an optical fiber.

A computer network may be an overlay network. An overlay network is a logical network implemented on top of another network such as a physical network. A node in an overlay network corresponds to a respective node in the underlying network. Hence, a node in an overlay network may be associated with both an overlay address (for data to be addressed to the overlay node) and an underlay address (for data to be addressed to the underlay node that implements the overlay node). An overlay node may be a digital device and/or a software process, such as a virtual machine, an application instance, or a thread. A link that connects overlay nodes is implemented as a tunnel through the underlying network. The overlay nodes at either end of the tunnel treat the underlying multi-hop path between them as a single logical link. Tunneling is performed through encapsulation and decapsulation.

In an embodiment, a client may be local to and/or remote from a computer network. The client may access the computer network over other computer networks, such as a private network or the Internet. The client may communicate requests to the computer network using a communications protocol such as Hypertext Transfer Protocol (HTTP). The requests are communicated through an interface, such as a client interface (such as a web browser), a program interface, or an application programming interface (API).

In an embodiment, a computer network provides connectivity between clients and network resources. Network resources include hardware and/or software configured to execute server processes. Examples of network resources include a processor, a data storage, a virtual machine, a container, and/or a software application. Network resources are shared amongst multiple clients. Clients request computing services from a computer network independently of other clients. Network resources are dynamically assigned to the requests and/or clients on an on-demand basis. Network resources assigned to a request and/or client may be scaled up or down based on one or more of the following: (a) the computing services requested by a particular client, (b) the aggregated computing services requested by a particular tenant, or (c) the aggregated computing services requested of the computer network. Such a computer network may be referred to as a “cloud network.”

In an embodiment, a service provider provides a cloud network to one or more end users. Various service models may be implemented by the cloud network, including, but not limited to, Software-as-a-Service (SaaS), Platform-as-a-Service (PaaS), and Infrastructure-as-a-Service (IaaS). In SaaS, a service provider provides end users the capability to use the service provider's applications that are executing on the network resources. In PaaS, the service provider provides end users the capability to deploy custom applications onto the network resources. The custom applications may be created using programming languages, libraries, services, and tools supported by the service provider. In IaaS, the service provider provides end users the capability to provision processing, storage, networks, and other fundamental computing resources provided by the network resources. Any arbitrary applications, including an operating system, may be deployed on the network resources.

In an embodiment, various deployment models may be implemented by a computer network, including, but not limited to, a private cloud, a public cloud, and a hybrid cloud. In a private cloud, network resources are provisioned for exclusive use by a particular group of one or more entities; the term “entity” as used herein refers to a corporation, organization, person, or other entity. The network resources may be local to and/or remote from the premises of the particular group of entities. In a public cloud, cloud resources may be provisioned for an entity that is independent from other entities (also referred to as “tenants” or “customers”). The computer network and the network resources thereof are accessed by clients corresponding to different tenants. Such a computer network may be referred to as a “multi-tenant computer network.” Several tenants may use a same particular network resource at different times and/or at the same time. The network resources may be local to and/or remote from the premises of the tenants. In a hybrid cloud, a computer network comprises a private cloud and a public cloud. An interface between the private cloud and the public cloud allows for data and application portability. Data stored at the private cloud and data stored at the public cloud may be exchanged through the interface. Applications implemented at the private cloud may have dependencies on applications implemented at the public cloud and vice-versa. A call from an application at the private cloud to an application at the public cloud (and vice versa) may be executed through the interface.

In an embodiment, a tenant of a multi-tenant computer network is independent of another tenant of the same multi-tenant computer network. For example, a business or operation of one tenant may be separate from a business or operation of another tenant. Different tenants may demand different network requirements for the computer network. Examples of network requirements include processing speed, amount of data storage, security requirements, performance requirements, throughput requirements, latency requirements, resiliency requirements, Quality of Service (QoS) requirements, tenant isolation, and/or consistency. The same computer network may need to implement different network requirements demanded by different tenants.

In one or more embodiments, in a multi-tenant computer network, tenant isolation is implemented to ensure that the applications and/or data of different tenants are not shared across tenants. Various tenant isolation approaches may be used.

In an embodiment, a tenant is associated with a tenant ID. A network resource of the multi-tenant computer network is tagged with a tenant ID. A tenant is permitted access to a particular network resource when the tenant and the particular network resources are associated with a same tenant ID.

In an embodiment, a tenant is associated with a tenant ID. An application, implemented by the computer network, is tagged with a tenant ID. Additionally, or alternatively, a data structure and/or dataset, stored by the computer network, is tagged with a tenant ID. A tenant is permitted access to a particular application, data structure, and/or dataset when the tenant and the particular application, data structure, and/or dataset are associated with a same tenant ID.

As an example, a database implemented by a multi-tenant computer network may be tagged with a tenant ID. A tenant associated with the corresponding tenant ID may access data of a particular database. As another example, an entry in a database implemented by a multi-tenant computer network may be tagged with a tenant ID. A tenant associated with the corresponding tenant ID may access data of a particular entry. However, multiple tenants may share the database.

In an embodiment, a subscription list identifies a set of tenants, and, for a tenant, a set of applications that the tenant is authorized to access. For an application, a list of tenant IDs of tenants authorized to access the application is stored. A tenant is permitted access to a particular application when the tenant ID of the tenant is implemented in the subscription list corresponding to the particular application.

In an embodiment, network resources (such as digital devices, virtual machines, application instances, and threads) corresponding to different tenants are isolated to tenant-specific overlay networks maintained by the multi-tenant computer network. As an example, packets from any source device in a tenant overlay network may be transmitted to other devices within the same tenant overlay network. Encapsulation tunnels are used to prohibit any transmissions from a source device on a tenant overlay network to devices in other tenant overlay networks. Specifically, the packets received from the source device are encapsulated within an outer packet. The outer packet is transmitted from a first encapsulation tunnel endpoint (in communication with the source device in the tenant overlay network) to a second encapsulation tunnel endpoint (in communication with the destination device in the tenant overlay network). The second encapsulation tunnel endpoint decapsulates the outer packet to obtain the original packet transmitted by the source device. The original packet is transmitted from the second encapsulation tunnel endpoint to the destination device in the same particular overlay network.

### 3. Examples of Cloud Networks

As noted above, infrastructure as a service (IaaS) is one particular type of cloud computing service. In an IaaS model, customers can build their own customizable virtual or overlay networks and deploy customer resources over on-demand, scalable computing resources of CI.

The CI may comprise interconnected high-performance compute resources including various host machines, memory resources, and network resources that form a physical network, which is also referred to as a substrate network or an underlay network. The resources in CI may be spread across one or more data centers that may be geographically spread across one or more geographical regions. Virtualization software may be executed by these physical resources to provide a virtualized distributed environment. The virtualization creates an overlay network (also known as a software-based network, a software-defined network, or a virtual network) over the physical network. The CI physical network provides the underlying basis for creating one or more overlay or virtual networks on top of the physical network. The physical network (or substrate network or underlay network) comprises physical network devices such as physical switches, routers, computers and host machines, and the like. An overlay network is a logical (or virtual) network that runs on top of a physical substrate network. A given physical network can support one or multiple overlay networks. Overlay networks typically use encapsulation techniques to differentiate between traffic belonging to different overlay networks. A virtual or overlay network is also referred to as a virtual cloud network (VCN). The virtual networks are implemented using software virtualization technologies (e.g., hypervisors, virtualization functions implemented by network virtualization devices (NVDs) (e.g., smartNICs), top-of-rack (TOR) switches, smart TORs that implement one or more functions performed by an NVD, and other mechanisms) to create layers of network abstraction that can be run on top of the physical network. Virtual networks can take on many forms, including peer-to-peer networks, IP networks, and others. Virtual networks are typically either Layer-3 IP networks or Layer-2 VLANs. This method of virtual or overlay networking is often referred to as virtual or overlay Layer-3 networking. Examples of protocols developed for virtual networks include IP-in-IP (or Generic Routing Encapsulation (GRE)) Virtual Extensible LAN (VXLAN-IETF RFC 7348), Virtual Private Networks (VPNs) (e.g., MPLS Layer-3 Virtual Private Networks (RFC 4364)), VMware's NSX, GENEVE (Generic Network Virtualization Encapsulation), and others.

In a physical network, a network endpoint (“endpoint”) refers to a computing device or system that is connected to a physical network and communicates back and forth with the network to which it is connected. A network endpoint in the physical network may be connected to a Local Area Network (LAN), a Wide Area Network (WAN), or other type of physical network. Examples of traditional endpoints in a physical network include modems, hubs, bridges, switches, routers, and other networking devices, physical computers (or host machines), and the like. Each physical device in the physical network has a fixed network address that can be used to communicate with the device. This fixed network address can be a Layer-2 address (e.g., a MAC address), a fixed Layer-3 address (e.g., an IP address), and the like. In a virtualized environment or in a virtual network, the endpoints can include various virtual endpoints such as virtual machines that are hosted by components of the physical network (e.g., hosted by physical host machines). These endpoints in the virtual network are addressed by overlay addresses such as overlay Layer-2 addresses (e.g., overlay MAC addresses) and overlay Layer-3 addresses (e.g., overlay IP addresses). Network overlays enable flexibility by allowing network managers to move around the overlay addresses associated with network endpoints using software management (e.g., via software implementing a control plane for the virtual network). Accordingly, unlike in a physical network, in a virtual network, an overlay address (e.g., an overlay IP address) can be moved from one endpoint to another using network management software. Since the virtual network is built on top of a physical network, communications between components in the virtual network involves both the virtual network and the underlying physical network. In order to facilitate such communications, the components of CI are configured to learn and store mappings that map overlay addresses in the virtual network to actual physical addresses in the substrate network, and vice versa. These mappings are then used to facilitate the communications. Customer traffic is encapsulated to facilitate routing in the virtual network.

Accordingly, physical addresses (e.g., physical IP addresses) are associated with components in physical networks and overlay addresses (e.g., overlay IP addresses) are associated with entities in virtual or overlay networks. A physical IP address is an IP address associated with a physical device (e.g., a network device) in the substrate or physical network. For example, each NVD has an associated physical IP address. An overlay IP address is an overlay address associated with an entity in an overlay network, such as with a compute instance in a customer's virtual cloud network (VCN). Two different customers or tenants, each with their own private VCNs can potentially use the same overlay IP address in their VCNs without any knowledge of each other. Both the physical IP addresses and overlay IP addresses are types of real IP addresses. These are separate from virtual IP addresses. A virtual IP address is typically a single IP address that represents or maps to multiple real IP addresses. A virtual IP address provides a 1-to-many mapping between the virtual IP address and multiple real IP addresses. For example, a load balancer may use a VIP to map to or represent multiple servers, each server having its own real IP address.

The cloud infrastructure or CI is physically hosted in one or more data centers in one or more regions around the world. The CI may include components in the physical or substrate network and virtualized components (e.g., virtual networks, compute instances, virtual machines, etc.) that are in a virtual network built on top of the physical network components. In certain embodiments, the CI is organized and hosted in realms, regions, and availability domains.

When a customer subscribes to an IaaS service, resources from CI are provisioned for the customer and associated with the customer's tenancy. The customer can use these provisioned resources to build private networks and deploy resources on these networks. The customer networks that are hosted in the cloud by the CI are referred to as virtual cloud networks (VCNs). A customer can set up one or more virtual cloud networks (VCNs) using CI resources allocated for the customer. A VCN is a virtual or software defined private network. The customer resources that are deployed in the customer's VCN can include compute instances (e.g., virtual machines, bare-metal instances) and other resources. These compute instances may represent various customer workloads such as applications, load balancers, databases, and the like. A compute instance deployed on a VCN can communicate with publicly accessible endpoints (“public endpoints”) over a public network such as the Internet, with other instances in the same VCN or other VCNs (e.g., the customer's other VCNs, or VCNs not belonging to the customer), with the customer's on-premise data centers or networks, and with service endpoints, and other types of endpoints. CI thus offers high-performance compute resources and storage capacity in flexible virtual networks that are securely accessible from various networked locations such as from a customer's on-premises network.

The CP may provide various services using the CI. In some instances, customers of CI may themselves act like service providers and provide services using CI resources. A service provider may expose a service endpoint, which is characterized by identification information (e.g., an IP Address, a DNS name and port). A customer's resource (e.g., a compute instance) can consume a particular service by accessing a service endpoint exposed by the service for that particular service. These service endpoints are generally endpoints that are publicly accessible by users using public IP addresses associated with the endpoints via a public communication network such as the Internet. Network endpoints that are publicly accessible are also sometimes referred to as public endpoints. In certain implementations, a service endpoint provided for a service can be accessed by multiple customers that intend to consume that service. In other implementations, a dedicated service endpoint may be provided for a customer such that only that customer can access the service using that dedicated service endpoint.

In certain embodiments, when a VCN is created, it is associated with a private overlay Classless Inter-Domain Routing (CIDR) address space, which is a range of private overlay IP addresses that are assigned to the VCN (e.g., 10.0/16). A VCN includes associated subnets, route tables, and gateways. A VCN resides within a single region but can span one or more or all of the region's availability domains. A gateway is a virtual interface that is configured for a VCN and enables communication of traffic to and from the VCN to one or more endpoints outside the VCN. One or more different types of gateways may be configured for a VCN to enable communication to and from different types of endpoints.

A VCN can be subdivided into one or more sub-networks such as one or more subnets. A subnet is thus a unit of configuration or a subdivision that can be created within a VCN. A VCN can have one or multiple subnets. Each subnet within a VCN is associated with a contiguous range of overlay IP addresses (e.g., 10.0.0.0/24 and 10.0.1.0/24) that do not overlap with other subnets in that VCN, and which represent an address space subset within the address space of the VCN.

Each compute instance is associated with a virtual network interface card (VNIC), that enables the compute instance to participate in a subnet of a VCN. A VNIC is a logical representation of physical Network Interface Card (NIC). In general. a VNIC is an interface between an entity (e.g., a compute instance, a service) and a virtual network. A VNIC exists in a subnet, has one or more associated IP addresses, and associated security rules or policies. A VNIC is equivalent to a Layer-2 port on a switch. A VNIC is attached to a compute instance and to a subnet within a VCN. A VNIC associated with a compute instance enables the compute instance to be a part of a subnet of a VCN and enables the compute instance to communicate (e.g., send and receive packets) with endpoints that are on the same subnet as the compute instance, with endpoints in different subnets in the VCN, or with endpoints outside the VCN. The VNIC associated with a compute instance thus determines how the compute instance connects with endpoints inside and outside the VCN. A VNIC for a compute instance is created and associated with that compute instance when the compute instance is created and added to a subnet within a VCN. For a subnet comprising a set of compute instances, the subnet contains the VNICs corresponding to the set of compute instances, each VNIC attached to a compute instance within the set of computer instances.

Each compute instance is assigned a private overlay IP address via the VNIC associated with the compute instance. This private overlay IP address is assigned to the VNIC that is associated with the compute instance when the compute instance is created and used for routing traffic to and from the compute instance. All VNICs in a given subnet use the same route table, security lists, and DHCP options. As described above, each subnet within a VCN is associated with a contiguous range of overlay IP addresses (e.g., 10.0.0.0/24 and 10.0.1.0/24) that do not overlap with other subnets in that VCN, and which represent an address space subset within the address space of the VCN. For a VNIC on a particular subnet of a VCN, the private overlay IP address that is assigned to the VNIC is an address from the contiguous range of overlay IP addresses allocated for the subnet.

In certain embodiments, a compute instance may optionally be assigned additional overlay IP addresses in addition to the private overlay IP address, such as, for example, one or more public IP addresses if in a public subnet. These multiple addresses are assigned either on the same VNIC or over multiple VNICs that are associated with the compute instance. Each instance however has a primary VNIC that is created during instance launch and is associated with the overlay private IP address assigned to the instance—this primary VNIC cannot be removed. Additional VNICs, referred to as secondary VNICs, can be added to an existing instance in the same availability domain as the primary VNIC. All the VNICs are in the same availability domain as the instance. A secondary VNIC can be in a subnet in the same VCN as the primary VNIC, or in a different subnet that is either in the same VCN or a different one.

A compute instance may optionally be assigned a public IP address if it is in a public subnet. A subnet can be designated as either a public subnet or a private subnet at the time the subnet is created. A private subnet means that the resources (e.g., compute instances) and associated VNICs in the subnet cannot have public overlay IP addresses. A public subnet means that the resources and associated VNICs in the subnet can have public IP addresses. A customer can designate a subnet to exist either in a single availability domain or across multiple availability domains in a region or realm.

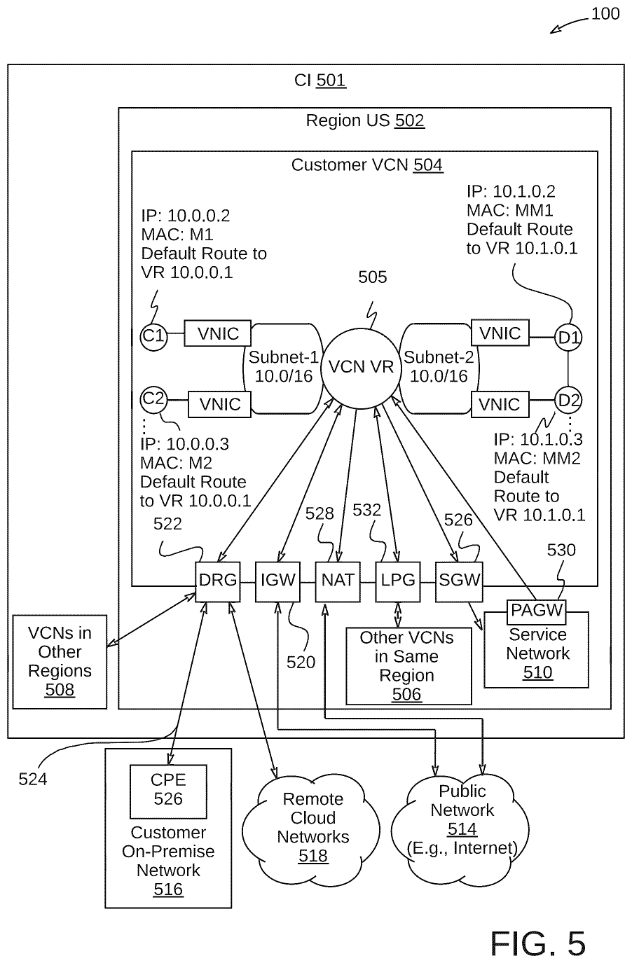

As described above, a VCN may be subdivided into one or more subnets. In certain embodiments, a Virtual Router (VR) configured for the VCN (referred to as the VCN VR or just VR) enables communications between the subnets of the VCN. For a subnet within a VCN, the VR represents a logical gateway for that subnet that enables the subnet (i.e., the compute instances on that subnet) to communicate with endpoints on other subnets within the VCN, and with other endpoints outside the VCN. The VCN VR is a logical entity that is configured to route traffic between VNICs in the VCN and virtual gateways (“gateways”) associated with the VCN. Gateways are further described below with respect to FIG. 5. A VCN VR is a Layer-3/IP Layer concept. In one embodiment, there is one VCN VR for a VCN where the VCN VR has potentially an unlimited number of ports addressed by IP addresses, with one port for each subnet of the VCN. In this manner, the VCN VR has a different IP address for each subnet in the VCN that the VCN VR is attached to. The VR is also connected to the various gateways configured for a VCN. In certain embodiments, a particular overlay IP address from the overlay IP address range for a subnet is reserved for a port of the VCN VR for that subnet. For example, consider a VCN having two subnets with associated address ranges 10.0/16 and 10.1/16, respectively. For the first subnet within the VCN with address range 10.0/16, an address from this range is reserved for a port of the VCN VR for that subnet. In some instances, the first IP address from the range may be reserved for the VCN VR. For example, for the subnet with overlay IP address range 10.0/16, IP address 10.0.0.1 may be reserved for a port of the VCN VR for that subnet. For the second subnet within the same VCN with address range 10.1/16, the VCN VR may have a port for that second subnet with IP address 10.1.0.1. The VCN VR has a different IP address for each of the subnets in the VCN.

In some other embodiments, each subnet within a VCN may have its own associated VR that is addressable by the subnet using a reserved or default IP address associated with the VR. The reserved or default IP address may, for example, be the first IP address from the range of IP addresses associated with that subnet. The VNICs in the subnet can communicate (e.g., send and receive packets) with the VR associated with the subnet using this default or reserved IP address. In such an embodiment, the VR is the ingress/egress point for that subnet. The VR associated with a subnet within the VCN can communicate with other VRs associated with other subnets within the VCN. The VRs can also communicate with gateways associated with the VCN. The VR function for a subnet is running on or executed by one or more NVDs executing VNICs functionality for VNICs in the subnet.

Route tables, security rules, and DHCP options may be configured for a VCN. Route tables are virtual route tables for the VCN and include rules to route traffic from subnets within the VCN to destinations outside the VCN by way of gateways or specially configured instances. A VCN's route tables can be customized to control how packets are forwarded/routed to and from the VCN. DHCP options refers to configuration information that is automatically provided to the instances when they boot up.

Security rules configured for a VCN represent overlay firewall rules for the VCN. The security rules can include ingress and egress rules, and specify the types of traffic (e.g., based upon protocol and port) that is allowed in and out of the instances within the VCN. The customer can choose whether a given rule is stateful or stateless. For instance, the customer can allow incoming SSH traffic from anywhere to a set of instances by setting up a stateful ingress rule with source CIDR 0.0.0.0/0, and destination TCP port 22. Security rules can be implemented using network security groups or security lists. A network security group consists of a set of security rules that apply only to the resources in that group. A security list, on the other hand, includes rules that apply to all the resources in any subnet that uses the security list. A VCN may be provided with a default security list with default security rules. DHCP options configured for a VCN provide configuration information that is automatically provided to the instances in the VCN when the instances boot up.

In certain embodiments, the configuration information for a VCN is determined and stored by a VCN Control Plane. The configuration information for a VCN may include, for example, information about the address range associated with the VCN, subnets within the VCN and associated information, one or more VRs associated with the VCN, compute instances in the VCN and associated VNICs, NVDs executing the various virtualization network functions (e.g., VNICs, VRs, gateways) associated with the VCN, state information for the VCN, and other VCN-related information. In certain embodiments, a VCN Distribution Service publishes the configuration information stored by the VCN Control Plane, or portions thereof, to the NVDs. The distributed information may be used to update information (e.g., forwarding tables, routing tables, etc.) stored and used by the NVDs to forward packets to and from the compute instances in the VCN.

In certain embodiments, the creation of VCNs and subnets are handled by a VCN Control Plane (CP), and the launching of compute instances is handled by a Compute Control Plane. The Compute Control Plane is responsible for allocating the physical resources for the compute instance and then calls the VCN Control Plane to create and attach VNICs to the compute instance. The VCN CP also sends VCN data mappings to the VCN data plane that is configured to perform packet forwarding and routing functions. In certain embodiments, the VCN CP provides a distribution service that is responsible for providing updates to the VCN data plane.

A customer may create one or more VCNs using resources hosted by CI. A compute instance deployed on a customer VCN may communicate with different endpoints. These endpoints can include endpoints that are hosted by CI and endpoints outside CI.

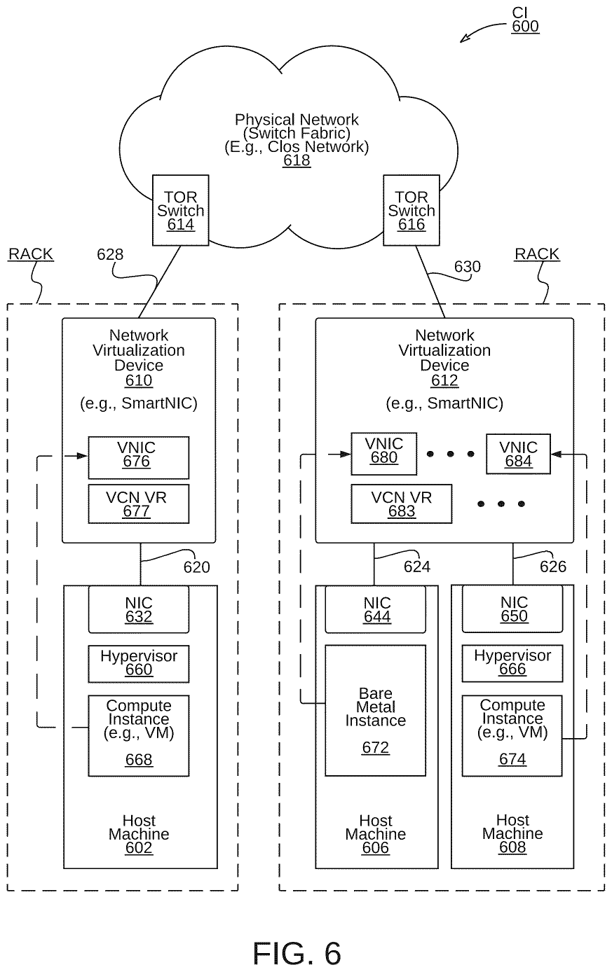

Various different architectures for implementing cloud-based service using CI are depicted in FIGS. 5-6, and are described below. FIG. 5 is a high-level diagram of a distributed environment 500 showing an overlay or customer VCN hosted by CI according to certain embodiments. The distributed environment depicted in FIG. 5 includes multiple components in the overlay network. Distributed environment 500 depicted in FIG. 5 is merely an example and is not intended to unduly limit the scope of claimed embodiments. Many variations, alternatives, and modifications are possible. For example, in some implementations, the distributed environment depicted in FIG. 5 may have more or fewer systems or components than those shown in FIG. 5, may combine two or more systems, or may have a different configuration or arrangement of systems.

As shown in the example depicted in FIG. 5, distributed environment 500 comprises CI 501 that provides services and resources that customers can subscribe to and use to build their virtual cloud networks (VCNs). In certain embodiments, CI 501 offers IaaS services to subscribing customers. The data centers within CI 501 may be organized into one or more regions. One example region “Region US” 502 is shown in FIG. 5. A customer has configured a customer VCN c/o Oracle International Corporation for region 502. The customer may deploy various compute instances on VCN 504, where the compute instances may include virtual machines or bare metal instances. Examples of instances include applications, database, load balancers, and the like.

In the embodiment depicted in FIG. 5, customer VCN 504 comprises two subnets, namely, “Subnet-1” and “Subnet-2”, each subnet with its own CIDR IP address range. In FIG. 5, the overlay IP address range for Subnet-1 is 10.0/16 and the address range for Subnet-2 is 10.1/16. A VCN Virtual Router 505 represents a logical gateway for the VCN that enables communications between subnets of the VCN 504, and with other endpoints outside the VCN. VCN VR 505 is configured to route traffic between VNICs in VCN 504 and gateways associated with VCN 504. VCN VR 505 provides a port for each subnet of VCN 504. For example, VR 505 may provide a port with IP address 10.0.0.1 for Subnet-1 and a port with IP address 10.1.0.1 for Subnet-2.

Multiple compute instances may be deployed on each subnet, where the compute instances can be virtual machine instances, and/or bare metal instances. The compute instances in a subnet may be hosted by one or more host machines within CI 501. A compute instance participates in a subnet via a VNIC associated with the compute instance. For example, as shown in FIG. 5, a compute instance C1 is part of Subnet-1 via a VNIC associated with the compute instance. Likewise, compute instance C2 is part of Subnet-1 via a VNIC associated with C2. In a similar manner, multiple compute instances, which may be virtual machine instances or bare metal instances, may be part of Subnet-1. Via its associated VNIC, each compute instance is assigned a private overlay IP address and a MAC address. For example, in FIG. 5, compute instance C1 has an overlay IP address of 10.0.0.2 and a MAC address of M1, while compute instance C2 has a private overlay IP address of 10.0.0.3 and a MAC address of M2. Each compute instance in Subnet-1, including compute instances C1 and C2, has a default route to VCN VR 505 using IP address 10.0.0.1, which is the IP address for a port of VCN VR 505 for Subnet-1.

Subnet-2 can have multiple compute instances deployed on it, including virtual machine instances and/or bare metal instances. For example, as shown in FIG. 5, compute instances D1 and D2 are part of Subnet-2 via VNICs associated with the respective compute instances. In the embodiment depicted in FIG. 5, compute instance D1 has an overlay IP address of 10.1.0.2 and a MAC address of MM1, while compute instance D2 has a private overlay IP address of 10.1.0.3 and a MAC address of MM2. Each compute instance in Subnet-2, including compute instances D1 and D2, has a default route to VCN VR 505 using IP address 10.1.0.1, which is the IP address for a port of VCN VR 505 for Subnet-2.

VCN 504 may also include one or more load balancers. For example, a load balancer may be provided for a subnet and may be configured to load balance traffic across multiple compute instances on the subnet. A load balancer may also be provided to load balance traffic across subnets in the VCN.

A particular compute instance deployed on VCN 504 can communicate with various different endpoints. These endpoints may include endpoints that are hosted by CI 600 and endpoints outside CI 600. Endpoints that are hosted by CI 501 may include: an endpoint on the same subnet as the particular compute instance (e.g., communications between two compute instances in Subnet-1); an endpoint on a different subnet but within the same VCN (e.g., communication between a compute instance in Subnet-1 and a compute instance in Subnet-2); an endpoint in a different VCN in the same region (e.g., communications between a compute instance in Subnet-1 and an endpoint in a VCN in the same region 506 or 510, communications between a compute instance in Subnet-1 and an endpoint in service network 510 in the same region); or an endpoint in a VCN in a different region (e.g., communications between a compute instance in Subnet-1 and an endpoint in a VCN in a different region 508). A compute instance in a subnet hosted by CI 501 may also communicate with endpoints that are not hosted by CI 501 (i.e., are outside CI 501). These outside endpoints include endpoints in the customer's on-premises network 516, endpoints within other remote cloud hosted networks 518, public endpoints 514 accessible via a public network such as the Internet, and other endpoints.

Communications between compute instances on the same subnet are facilitated using VNICs associated with the source compute instance and the destination compute instance. For example, compute instance C1 in Subnet-1 may want to send packets to compute instance C2 in Subnet-1. For a packet originating at a source compute instance and whose destination is another compute instance in the same subnet, the packet is first processed by the VNIC associated with the source compute instance. Processing performed by the VNIC associated with the source compute instance can include determining destination information for the packet from the packet headers, identifying any policies (e.g., security lists) configured for the VNIC associated with the source compute instance, determining a next hop for the packet, performing any packet encapsulation/decapsulation functions as needed, and then forwarding/routing the packet to the next hop with the goal of facilitating communication of the packet to its intended destination. When the destination compute instance is in the same subnet as the source compute instance, the VNIC associated with the source compute instance is configured to identify the VNIC associated with the destination compute instance and forward the packet to that VNIC for processing. The VNIC associated with the destination compute instance is then executed and forwards the packet to the destination compute instance.

For a packet to be communicated from a compute instance in a subnet to an endpoint in a different subnet in the same VCN, the communication is facilitated by the VNICs associated with the source and destination compute instances and the VCN VR. For example, if compute instance C1 in Subnet-1 in FIG. 5 wants to send a packet to compute instance D1 in Subnet-2, the packet is first processed by the VNIC associated with compute instance C1. The VNIC associated with compute instance C1 is configured to route the packet to the VCN VR 505 using default route or port 10.0.0.1 of the VCN VR. VCN VR 505 is configured to route the packet to Subnet-2 using port 10.1.0.1. The packet is then received and processed by the VNIC associated with D1 and the VNIC forwards the packet to compute instance D1.

For a packet to be communicated from a compute instance in VCN 504 to an endpoint that is outside VCN 504, the communication is facilitated by the VNIC associated with the source compute instance, VCN VR 505, and gateways associated with VCN 504. One or more types of gateways may be associated with VCN 504. A gateway is an interface between a VCN and another endpoint, where another endpoint is outside the VCN. A gateway is a Layer-3/IP layer concept and enables a VCN to communicate with endpoints outside the VCN. A gateway thus facilitates traffic flow between a VCN and other VCNs or networks. Various different types of gateways may be configured for a VCN to facilitate different types of communications with different types of endpoints. Depending upon the gateway, the communications may be over public networks (e.g., the Internet) or over private networks. Various communication protocols may be used for these communications.

For example, compute instance C1 may want to communicate with an endpoint outside VCN 504. The packet may be first processed by the VNIC associated with source compute instance C1. The VNIC processing determines that the destination for the packet is outside the Subnet-1 of C1. The VNIC associated with C1 may forward the packet to VCN VR 505 for VCN 504. VCN VR 505 then processes the packet and as part of the processing, based upon the destination for the packet, determines a particular gateway associated with VCN 504 as the next hop for the packet. VCN VR 505 may then forward the packet to the particular identified gateway. For example, if the destination is an endpoint within the customer's on-premise network, then the packet may be forwarded by VCN VR 505 to Dynamic Routing Gateway (DRG) gateway 522 configured for VCN 504. The packet may then be forwarded from the gateway to a next hop to facilitate communication of the packet to it final intended destination.

Various different types of gateways may be configured for a VCN. Examples of gateways that may be configured for a VCN are depicted in FIG. 5 and described below. As shown in the embodiment depicted in FIG. 5, a Dynamic Routing Gateway (DRG) 522 may be added to or be associated with customer VCN 504 and provides a path for private network traffic communication between customer VCN 504 and another endpoint, where another endpoint can be the customer's on-premise network 516, a VCN 508 in a different region of CI 501, or other remote cloud networks 518 not hosted by CI 501. Customer on-premise network 516 may be a customer network or a customer data center built using the customer's resources. Access to customer on-premise network 516 is generally very restricted. For a customer that has both a customer on-premise network 516 and one or more VCNs 504 deployed or hosted in the cloud by CI 501, the customer may want their on-premise network 516 and their cloud based VCN 504 to be able to communicate with each other. This enables a customer to build an extended hybrid environment encompassing the customer's VCN 504 hosted by CI 501 and their on-premises network 516. DRG 522 enables this communication. To enable such communications, a communication channel 524 is set up where one endpoint of the channel is in customer on-premise network 516 and the other endpoint is in CI 501 and connected to customer VCN 504. Communication channel 524 can be over public communication networks such as the Internet or private communication networks. Various different communication protocols may be used such as IPsec VPN technology over a public communication network such as the Internet, Oracle's FastConnect technology that uses a private network instead of a public network, and others. The device or equipment in customer on-premise network 516 that forms one end point for communication channel 524 is referred to as the customer premise equipment (CPE), such as CPE 526 depicted in FIG. 5. On the CI 501 side, the endpoint may be a host machine executing DRG 522.

In certain embodiments, a Remote Peering Connection (RPC) can be added to a DRG, which allows a customer to peer one VCN with another VCN in a different region. Using such an RPC, customer VCN 504 can use DRG 522 to connect with a VCN 508 in another region. DRG 522 may also be used to communicate with other remote cloud networks 518, not hosted by CI 501 such as a Microsoft Azure cloud, Amazon AWS cloud, and others.

As shown in FIG. 5, an Internet Gateway (IGW) 520 may be configured for customer VCN 504 the enables a compute instance on VCN 504 to communicate with public endpoints 514 accessible over a public network such as the Internet. IGW 520 is a gateway that connects a VCN to a public network such as the Internet. IGW 520 enables a public subnet (where the resources in the public subnet have public overlay IP addresses) within a VCN, such as VCN 504, direct access to public endpoints 512 on a public network 514 such as the Internet. Using IGW 520, connections can be initiated from a subnet within VCN 504 or from the Internet.

A Network Address Translation (NAT) gateway 528 can be configured for customer's VCN 504 and enables cloud resources in the customer's VCN, which do not have dedicated public overlay IP addresses, access to the Internet and it does so without exposing those resources to direct incoming Internet connections (e.g., L4-L7 connections). This enables a private subnet within a VCN, such as private Subnet-1 in VCN 504, with private access to public endpoints on the Internet. In NAT gateways, connections can be initiated only from the private subnet to the public Internet and not from the Internet to the private subnet.

In certain embodiments, a Service Gateway (SGW) 526 can be configured for customer VCN 504 and provides a path for private network traffic between VCN 504 and supported services endpoints in a service network 510. In certain embodiments, service network 510 may be provided by the CP and may provide various services. An example of such a service network is Oracle's Services Network, which provides various services that can be used by customers. For example, a compute instance (e.g., a database system) in a private subnet of customer VCN 504 can back up data to a service endpoint (e.g., Object Storage) without needing public IP addresses or access to the Internet. In certain embodiments, a VCN can have only one SGW, and connections can only be initiated from a subnet within the VCN and not from service network 510. If a VCN is peered with another, resources in the other VCN typically cannot access the SGW. Resources in on-premises networks that are connected to a VCN with FastConnect or VPN Connect can also use the service gateway configured for that VCN.

In certain implementations, SGW 526 uses the concept of a service Classless Inter-Domain Routing (CIDR) label, which is a string that represents all the regional public IP address ranges for the service or group of services of interest. The customer uses the service CIDR label when they configure the SGW and related route rules to control traffic to the service. The customer can optionally utilize it when configuring security rules without needing to adjust them if the service's public IP addresses change in the future.

A Local Peering Gateway (LPG) 532 is a gateway that can be added to customer VCN 504 and enables VCN 504 to peer with another VCN in the same region. Peering means that the VCNs communicate using private IP addresses, without the traffic traversing a public network such as the Internet or without routing the traffic through the customer's on-premises network 516. In preferred embodiments, a VCN has a separate LPG for each peering it establishes. Local Peering or VCN Peering is a common practice used to establish network connectivity between different applications or infrastructure management functions.

Service providers, such as providers of services in service network 510, may provide access to services using different access models. According to a public access model, services may be exposed as public endpoints that are publicly accessible by compute instance in a customer VCN via a public network such as the Internet and or may be privately accessible via SGW 526. According to a specific private access model, services are made accessible as private IP endpoints in a private subnet in the customer's VCN. This is referred to as a Private Endpoint (PE) access and enables a service provider to expose their service as an instance in the customer's private network. A Private Endpoint resource represents a service within the customer's VCN. Each PE manifests as a VNIC (referred to as a PE-VNIC, with one or more private IPs) in a subnet chosen by the customer in the customer's VCN. A PE thus provides a way to present a service within a private customer VCN subnet using a VNIC. Since the endpoint is exposed as a VNIC, all the features associates with a VNIC such as routing rules, security lists, etc., are now available for the PE VNIC.

A service provider can register their service to enable access through a PE. The provider can associate policies with the service that restricts the service's visibility to the customer tenancies. A provider can register multiple services under a single virtual IP address (VIP), especially for multi-tenant services. There may be multiple such private endpoints (in multiple VCNs) that represent the same service.

Compute instances in the private subnet can then use the PE VNIC's private IP address or the service DNS name to access the service. Compute instances in the customer VCN can access the service by sending traffic to the private IP address of the PE in the customer VCN. A Private Access Gateway (PAGW) 530 is a gateway resource that can be attached to a service provider VCN (e.g., a VCN in service network 510) that acts as an ingress/egress point for all traffic from/to customer subnet private endpoints. PAGW 530 enables a provider to scale the number of PE connections without utilizing its internal IP address resources. A provider needs only configure one PAGW for any number of services registered in a single VCN. Providers can represent a service as a private endpoint in multiple VCNs of one or more customers. From the customer's perspective, the PE VNIC, which, instead of being attached to a customer's instance, appears attached to the service with which the customer wishes to interact. The traffic destined to the private endpoint is routed via PAGW 530 to the service. These are referred to as customer-to-service private connections (C2S connections).

The PE concept can also be used to extend the private access for the service to customer's on-premises networks and data centers, by allowing the traffic to flow through FastConnect/IPsec links and the private endpoint in the customer VCN. Private access for the service can also be extended to the customer's peered VCNs, by allowing the traffic to flow between LPG 532 and the PE in the customer's VCN.

A customer can control routing in a VCN at the subnet level, so the customer can specify which subnets in the customer's VCN, such as VCN 504, use each gateway. A VCN's route tables are used to decide if traffic is allowed out of a VCN through a particular gateway. For example, in a particular instance, a route table for a public subnet within customer VCN 504 may send non-local traffic through IGW 520. The route table for a private subnet within the same customer VCN 504 may send traffic destined for CP services through SGW 526. All remaining traffic may be sent via the NAT gateway 528. Route tables only control traffic going out of a VCN.

Security lists associated with a VCN are used to control traffic that comes into a VCN via a gateway via inbound connections. All resources in a subnet use the same route table and security lists. Security lists may be used to control specific types of traffic allowed in and out of instances in a subnet of a VCN. Security list rules may comprise ingress (inbound) and egress (outbound) rules. For example, an ingress rule may specify an allowed source address range, while an egress rule may specify an allowed destination address range. Security rules may specify a particular protocol (e.g., TCP, ICMP), a particular port (e.g., 22 for SSH, 3389 for Windows RDP), etc. In certain implementations, an instance's operating system may enforce its own firewall rules that are aligned with the security list rules. Rules may be stateful (e.g., a connection is tracked, and the response is automatically allowed without an explicit security list rule for the response traffic) or stateless.

Access from a customer VCN (i.e., by a resource or compute instance deployed on VCN 504) can be categorized as public access, private access, or dedicated access. Public access refers to an access model where a public IP address or a NAT is used to access a public endpoint. Private access enables customer workloads in VCN 504 with private IP addresses (e.g., resources in a private subnet) to access services without traversing a public network such as the Internet. In certain embodiments, CI 501 enables customer VCN workloads with private IP addresses to access the (public service endpoints of) services using a service gateway. A service gateway thus offers a private access model by establishing a virtual link between the customer's VCN and the service's public endpoint residing outside the customer's private network.

Additionally, CI may offer dedicated public access using technologies such as FastConnect public peering where customer on-premises instances can access one or more services in a customer VCN using a FastConnect connection and without traversing a public network such as the Internet. CI also may also offer dedicated private access using FastConnect private peering where customer on-premises instances with private IP addresses can access the customer's VCN workloads using a FastConnect connection. FastConnect is a network connectivity alternative to using the public Internet to connect a customer's on-premise network to CI and its services. FastConnect provides an easy, elastic, and economical way to create a dedicated and private connection with higher bandwidth options and a more reliable and consistent networking experience when compared to Internet-based connections.

FIG. 5 and the accompanying description above describes various virtualized components in an example virtual network. As described above, the virtual network is built on the underlying physical or substrate network. FIG. 6 depicts a simplified architectural diagram of the physical components in the physical network within CI 600 that provide the underlay for the virtual network according to certain embodiments. As shown, CI 600 provides a distributed environment comprising components and resources (e.g., compute, memory, and networking resources) provided by a cloud service provider (CP). These components and resources are used to provide cloud services (e.g., IaaS services) to subscribing customers, i.e., customers that have subscribed to one or more services provided by the CP. Based upon the services subscribed to by a customer, a subset of resources (e.g., compute, memory, and networking resources) of CI 600 are provisioned for the customer. Customers can then build their own cloud-based (i.e., CI-hosted) customizable and private virtual networks using physical compute, memory, and networking resources provided by CI 600. As previously indicated, these customer networks are referred to as virtual cloud networks (VCNs). A customer can deploy one or more customer resources, such as compute instances, on these customer VCNs. Compute instances can be in the form of virtual machines, bare metal instances, and the like. CI 600 provides infrastructure and a set of complementary cloud services that enable customers to build and run a wide range of applications and services in a highly available hosted environment.

In the example embodiment depicted in FIG. 6, the physical components of CI 600 include one or more physical host machines or physical servers (e.g., 602, 606, 608), network virtualization devices (NVDs) (e.g., 610, 612), top-of-rack (TOR) switches (e.g., 614, 616), and a physical network (e.g., 618), and switches in physical network 618. The physical host machines or servers may host and execute various compute instances that participate in one or more subnets of a VCN. The compute instances may include virtual machine instances, and bare metal instances. For example, the various compute instances depicted in FIG. 5 may be hosted by the physical host machines depicted in FIG. 6. The virtual machine compute instances in a VCN may be executed by one host machine or by multiple different host machines. The physical host machines may also host virtual host machines, container-based hosts or functions, and the like. The VNICs and VCN VR depicted in FIG. 5 may be executed by the NVDs depicted in FIG. 6. The gateways depicted in FIG. 5 may be executed by the host machines and/or by the NVDs depicted in FIG. 6.

The host machines or servers may execute a hypervisor (also referred to as a virtual machine monitor or VMM) that creates and enables a virtualized environment on the host machines. The virtualization or virtualized environment facilitates cloud-based computing. One or more compute instances may be created, executed, and managed on a host machine by a hypervisor on that host machine. The hypervisor on a host machine enables the physical computing resources of the host machine (e.g., compute, memory, and networking resources) to be shared between the various compute instances executed by the host machine.

For example, as depicted in FIG. 6, host machines 602 and 608 execute hypervisors 660 and 666, respectively. These hypervisors may be implemented using software, firmware, or hardware, or combinations thereof. Typically, a hypervisor is a process or a software layer that sits on top of the host machine's operating system (OS), which in turn executes on the hardware processors of the host machine. The hypervisor provides a virtualized environment by enabling the physical computing resources (e.g., processing resources such as processors/cores, memory resources, networking resources) of the host machine to be shared among the various virtual machine compute instances executed by the host machine. For example, in FIG. 6, hypervisor 660 may sit on top of the OS of host machine 602 and enables the computing resources (e.g., processing, memory, and networking resources) of host machine 602 to be shared between compute instances (e.g., virtual machines) executed by host machine 602. A virtual machine can have its own operating system (referred to as a guest operating system), which may be the same as or different from the OS of the host machine. The operating system of a virtual machine executed by a host machine may be the same as or different from the operating system of another virtual machine executed by the same host machine. A hypervisor thus enables multiple operating systems to be executed alongside each other while sharing the same computing resources of the host machine. The host machines depicted in FIG. 6 may have the same or different types of hypervisors.

A compute instance can be a virtual machine instance or a bare metal instance. In FIG. 6, compute instances 668 on host machine 602 and 674 on host machine 608 are examples of virtual machine instances. Host machine 606 is an example of a bare metal instance that is provided to a customer.

In certain instances, an entire host machine may be provisioned to a single customer, and all of the one or more compute instances (either virtual machines or bare metal instance) hosted by that host machine belong to that same customer. In other instances, a host machine may be shared between multiple customers (i.e., multiple tenants). In such a multi-tenancy scenario, a host machine may host virtual machine compute instances belonging to different customers. These compute instances may be members of different VCNs of different customers. In certain embodiments, a bare metal compute instance is hosted by a bare metal server without a hypervisor. When a bare metal compute instance is provisioned, a single customer or tenant maintains control of the physical CPU, memory, and network interfaces of the host machine hosting the bare metal instance and the host machine is not shared with other customers or tenants.

As previously described, each compute instance that is part of a VCN is associated with a VNIC that enables the compute instance to become a member of a subnet of the VCN. The VNIC associated with a compute instance facilitates the communication of packets or frames to and from the compute instance. A VNIC is associated with a compute instance when the compute instance is created. In certain embodiments, for a compute instance executed by a host machine, the VNIC associated with that compute instance is executed by an NVD connected to the host machine. For example, in FIG. 6, host machine 602 executes a virtual machine compute instance 668 that is associated with VNIC 676, and VNIC 676 is executed by NVD 610 connected to host machine 602. As another example, bare metal instance 672 hosted by host machine 606 is associated with VNIC 680 that is executed by NVD 612 connected to host machine 606. As yet another example, VNIC 684 is associated with compute instance 674 executed by host machine 608, and VNIC 684 is executed by NVD 612 connected to host machine 608.

For compute instances hosted by a host machine, an NVD connected to that host machine also executes VCN VRs corresponding to VCNs of which the compute instances are members. For example, in the embodiment depicted in FIG. 6, NVD 610 executes VCN VR 677 corresponding to the VCN of which compute instance 668 is a member. NVD 612 may also execute one or more VCN VRs 683 corresponding to VCNs corresponding to the compute instances hosted by host machines 606 and 608.

A host machine may include one or more network interface cards (NIC) that enable the host machine to be connected to other devices. A NIC on a host machine may provide one or more ports (or interfaces) that enable the host machine to be communicatively connected to another device. For example, a host machine may be connected to an NVD using one or more ports (or interfaces) provided on the host machine and on the NVD. A host machine may also be connected to other devices such as another host machine.

For example, in FIG. 6, host machine 602 is connected to NVD 610 using link 620 that extends between a port 634 provided by a NIC 632 of host machine 602 and between a port 636 of NVD 610. Host machine 606 is connected to NVD 612 using link 624 that extends between a port 646 provided by a NIC 644 of host machine 606 and between a port 648 of NVD 612. Host machine 608 is connected to NVD 612 using link 626 that extends between a port 652 provided by a NIC 650 of host machine 608 and between a port 654 of NVD 612.

The NVDs are in turn connected via communication links to top-of-the-rack (TOR) switches, which are connected to physical network 618 (also referred to as the switch fabric). In certain embodiments, the links between a host machine and an NVD, and between an NVD and a TOR switch are Ethernet links. For example, in FIG. 6, NVDs 610 and 612 are connected to TOR switches 614 and 616, respectively, using links 628 and 630. In certain embodiments, the links 620, 624, 626, 628, and 630 are Ethernet links. The collection of host machines and NVDs that are connected to a TOR is sometimes referred to as a rack.

Physical network 618 provides a communication fabric that enables TOR switches to communicate with each other. A communication fabric, also called network fabric or fabric, refers to a physical network structure that includes a set of interconnected switches that provide multiple redundant pathways for data flow between a set of computing devices. A fabric enables high-throughput, low-latency communication through structured, multi-path routing. A fabric has a topology that defines a physical layout and arrangement of the set of interconnected switches and links. The physical layout and arrangement of the set of interconnected switches and links define pathways for data to flow across the fabric. In an embodiment, physical network 618 can be a multi-tiered network. In certain implementations, physical network 618 is a multi-tiered Clos network of switches, with TOR switches 614 and 616 representing the leaf level nodes of the multi-tiered and multi-node physical switching network 618. Example network fabrics employing different network topologies, such as a Clos topology, are further described below in the Section titled “Example Network Fabrics.”

### 4. Example Network Fabrics

Computing components located in the various racks of a data center are interconnected to one another by fabric. The term “network fabric” or “fabric” generally refers to a physical network structure that includes a set of interconnected switches that provide multiple redundant pathways for data flow between a set of computing devices. A fabric enables high-throughput, low-latency communication through structured, multi-path routing.

A fabric is associated with a topology that defines a physical layout and arrangement of the set of interconnected switches and links. The physical layout and arrangement of the set of interconnected switches and links define pathways for data to flow across the fabric. An example network topology is multi-tiered Clos topology. A multi-tiered Clos topology is a type of non-blocking, multistage or multi-tiered switching network topology, where the number of stages or tiers can be two, three, four, five, etc. A Clos network with “n” stages may be referred to as a “n”-tiered network. Each switch in “tier n” is connected to each switch in “tier n+1.” In a 2-tier spine, t1 may be referred to a leaf layer, and t2 may be referred to as a spine layer. The spine layer can server as a high-speed backbone, interacting with the leaf layer.

A fabric can include different groups of switches and clients, referred to as “fabric groups” and “client groups,” arranged in various variations or arrangements of network topologies. Each tier of the fabric includes one or more fabric groups. The leaf tier includes one or more client groups (e.g., computing servers, GPU servers, and/or end devices). A “role” of a fabric group is associated with the tier of the fabric group. For example, a role of a fabric group in t1 may be “leaf”; and a role of a fabric group in t2 may be “spine.”

Each fabric group has a defined number of switches. Each switch has one or more south-facing ports, also called “downlinks,” and one or more north-facing ports, also called “uplinks.” The south-facing ports of switches in a fabric group of an upper tier may be connected to the north-facing ports of switches in a fabric group of a lower tier.

The configuration of connections between switches of fabric groups of adjacent tiers may be referred to as “linking configurations” or “linking rules.” Examples of linking configurations include a full mesh configuration, or a partial mesh configuration. In a full mesh configuration, every south-facing port of switches of an upper fabric group is directly connected to every north-facing port of switches of a lower fabric group. The non-blocking configuration allows connections to be made between switches in adjacent tiers without interference from currently established connections. Various cablings options may be used to implement the links, such as Active Optical Connectors (AOCs); high-speed optical transceivers that uses Coarse Wavelength Division Multiplexing (CWDM); and/or high-speed, hot-pluggable, low-power-dissipation optical transceivers.

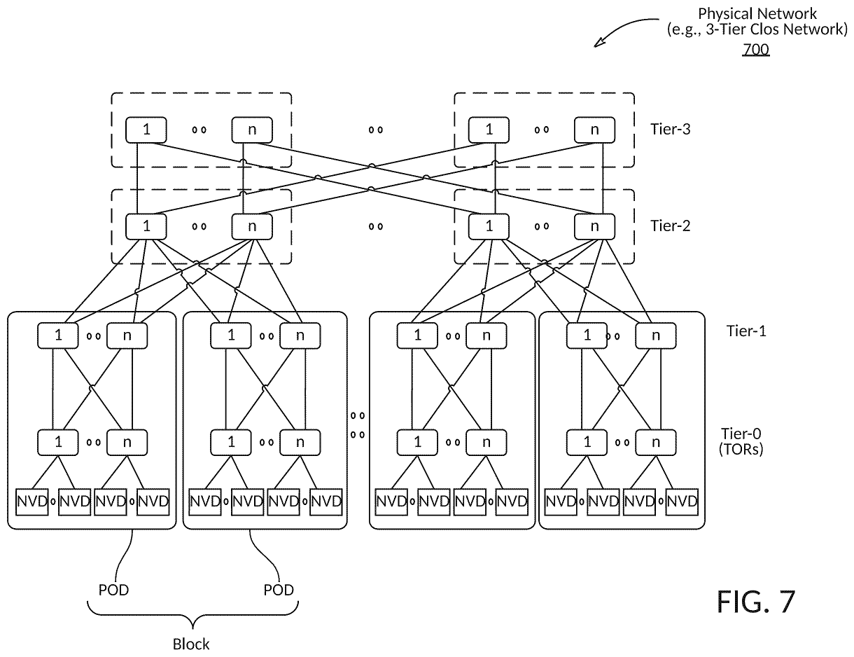

FIG. 7 depicts a simplified block diagram of a physical network 700 structured as a Clos network according to certain embodiments. The embodiment depicted in FIG. 7 is a 3-tiered network comprising tiers 1, 2, and 3. The TOR switches represent Tier-0 switches in the Clos network. One or more NVDs are connected to the TOR switches. Tier-0 switches are also referred to as edge devices of the physical network. The Tier-0 switches are connected to Tier-1 switches (also referred to as leaf switches). In the embodiment depicted in FIG. 7, a set of “n” Tier-0 TOR switches are connected to a set of “n” Tier-1 switches and together form a pod. Each Tier-0 switch in a pod is interconnected to all the Tier-1 switches in the pod, but there is no connectivity of switches between pods. In certain implementations, two pods are referred to as a block. Each block is served by or connected to a set of “n” Tier-2 switches (sometimes referred to as spine switches). There can be several blocks in the physical network topology. The Tier-2 switches are in turn connected to “n” Tier-3 switches (sometimes referred to as super-spine switches). Communication of packets over physical network 500 is typically performed using one or more Layer-3 communication protocols. Typically, all the layers of the physical network, except for the TORs layer are n-ways redundant thus allowing for high availability. Policies may be specified for pods and blocks to control the visibility of switches to each other in the physical network so as to enable scaling of the physical network.

A feature of a Clos network is that the maximum hop count to reach from one Tier-0 switch to another Tier-0 switch (or from an NVD connected to a Tier-0-switch to another NVD connected to a Tier-0 switch) is fixed. For example, in a 3-Tiered Clos network at most seven hops are needed for a packet to reach from one NVD to another NVD, where the source and target NVDs are connected to the leaf tier of the Clos network. Likewise, in a 4-tiered Clos network, at most nine hops are needed for a packet to reach from one NVD to another NVD, where the source and target NVDs are connected to the leaf tier of the Clos network. Thus, a Clos network architecture maintains consistent latency throughout the network, which is important for communication within and between data centers. A Clos topology scales horizontally and is cost effective. The bandwidth/throughput capacity of the network can be easily increased by adding more switches at the various tiers (e.g., more leaf and spine switches) and by increasing the number of links between the switches at adjacent tiers.

In an embodiment, a single site implements multiple networks, each implemented by one or more network fabrics. Each network in a site may serve a different purpose, such as a front-end network, a back-end network, a management network, and/or other networks. Each network fabric in a site may be implemented using a different network topology or a different combination of network topologies.

As examples, a compute network fabric architecture (CNFA) is configured to connect with non-network racks (compute, storage, service enclave, etc.) within a datacenter. CNFA may be implemented as a 3-tier Clos network. A junction network fabric architecture (JNFA) is configured to connect with network device roles, including: CNFAs; internet gateways; dedicated private connections to on-premise datacenters of customers; and backbone devices. JNFA may be implemented as a 2-tier Clos network. A management network fabric architecture (MNFA) is configured to connect with management devices. In an example, a site includes a CNFA, JNDA, and MNFA. The CNFA may include multiple (e.g., six) blocks. For external connectivity, a subset of t2 blocks (e.g., one t2 block) of the CNFA in a site is dedicated to connecting to t1 switches of the JNFA (rather than t3 super-spine switches of the CNFA, as described above). Further, one or more t1 switches of the JNFA are dedicated to connecting to t1 switches of the MNFA.

As further examples, performance network fabric architectures (PNFA) may be used. PNFA provides connectivity for cluster networks, such as high-performance computer (HPC) networks, high-performance database platform networks, and GPU networks. PNFA enables fine-grained traffic engineering that supports Quality of Service (QoS), which is a set of technologies that manage network traffic to prioritize critical applications. PNFA supports RDMA over Converged Ethernet (e.g., RoCE v1 and/or ROCEv2), Virtual extensible Local-Area Network (VXLAN), dynamic load balancing (DLB), Dot1x, etc. Different variants of PNFA have different numbers of tiers, e.g., two, three. In an example, a site may include a CNFA and a PNFA. “RDMA” or “Remote Direct Memory Access” generally refers to a technology that allows computing devices to access each other's memory directly without using the operating system.

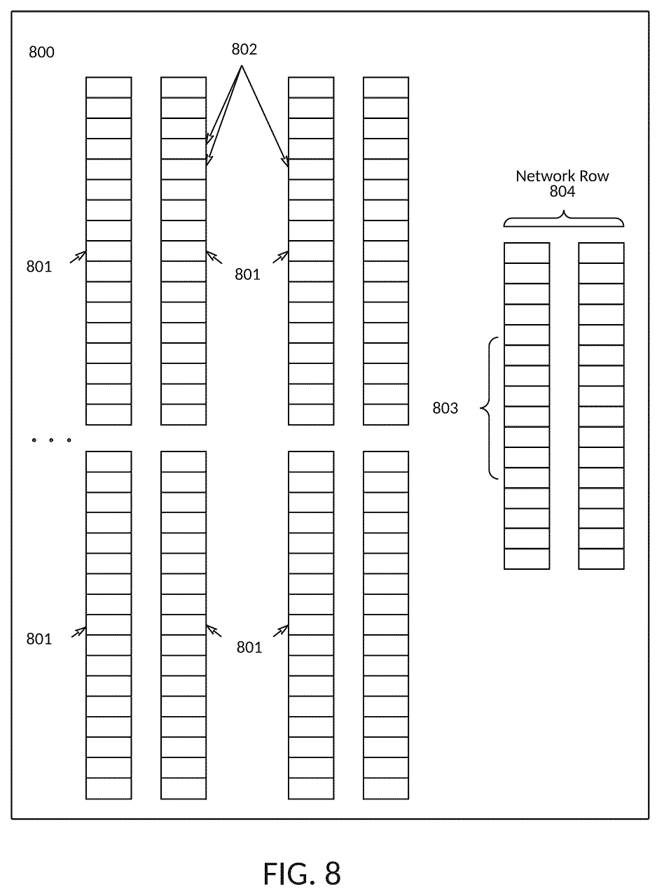

A fabric topology is implemented by physical racks of switches. In an embodiment, each block of switches in a network fabric is implemented in separate racks within a datacenter. FIG. 8 depicts a data hall 800 containing rows of compute racks and network racks, with the network racks implementing a network fabric, according to certain embodiments. The leaf block racks 801 may be located on the data hall floor adjacent to host-containing racks 802, effectively providing the data hall with functionality of an intermediate distribution frame (IDF). The spine block racks 803 may be located in a network row 804 in the data hall 800, effectively providing the data hall with functionality of a main distribution frame (MDF). Several data halls can be combined to provide a data center with a larger capacity.

### 5. Hardware Overview

According to one embodiment, the techniques described herein are implemented by one or more special-purpose computing devices. The special-purpose computing devices may be hard-wired to perform the techniques, or may include digital electronic devices such as one or more application-specific integrated circuits (ASICs), field programmable gate arrays (FPGAs), or network processing units (NPUs) that are persistently programmed to perform the techniques, or may include one or more general purpose hardware processors programmed to perform the techniques pursuant to program instructions in firmware, memory, other storage, or a combination. Such special-purpose computing devices may also combine custom hard-wired logic, ASICs, FPGAs, or NPUs with custom programming to accomplish the techniques. The special-purpose computing devices may be desktop computer systems, portable computer systems, handheld devices, networking devices or any other device that incorporates hard-wired and/or program logic to implement the techniques.

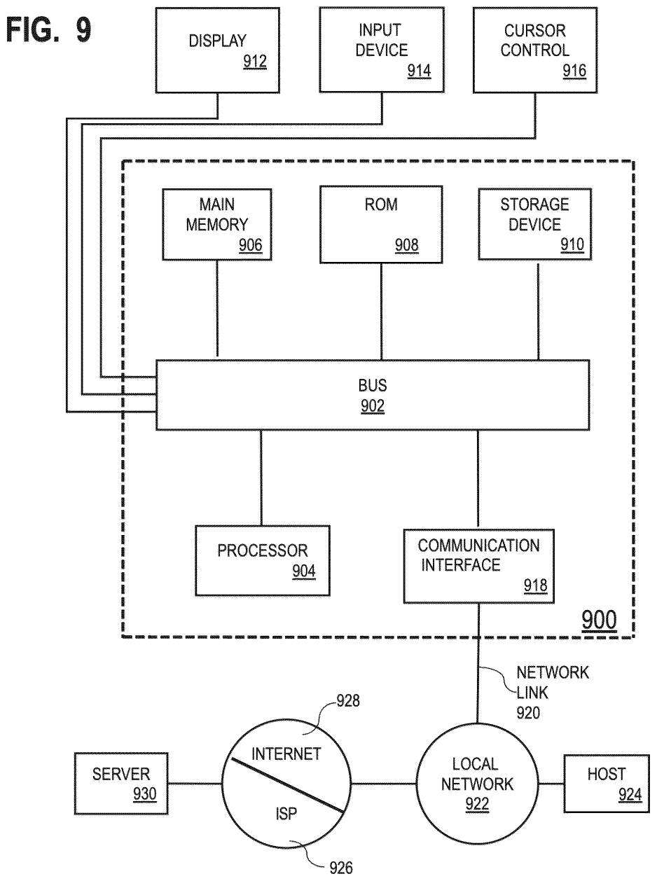

For example, FIG. 9 is a block diagram that illustrates a computer system 900 upon which an embodiment of the disclosure may be implemented. Computer system 900 includes a bus 902 or other communication mechanism for communicating information, and a hardware processor 904 coupled with bus 902 for processing information. Hardware processor 904 may be, for example, a general purpose microprocessor.

Computer system 900 also includes a main memory 906, such as a random access memory (RAM) or other dynamic storage device, coupled to bus 902 for storing information and instructions to be executed by processor 904. Main memory 906 also may be used for storing temporary variables or other intermediate information during execution of instructions to be executed by processor 904. Such instructions, when stored in non-transitory storage media accessible to processor 904, render computer system 900 into a special-purpose machine that is customized to perform the operations specified in the instructions.

Computer system 900 further includes a read only memory (ROM) 908 or other static storage device coupled to bus 902 for storing static information and instructions for processor 904. A storage device 910, such as a magnetic disk, optical disk, or a Solid State Drive (SSD) is provided and coupled to bus 902 for storing information and instructions.

Computer system 900 may be coupled via bus 902 to a display 912, such as a cathode ray tube (CRT), for displaying information to a computer user. An input device 914, including alphanumeric and other keys, is coupled to bus 902 for communicating information and command selections to processor 904. Another type of user input device is cursor control 916, such as a mouse, a trackball, or cursor direction keys for communicating direction information and command selections to processor 904 and for controlling cursor movement on display 912. This input device typically has two degrees of freedom in two axes, a first axis (e.g., x) and a second axis (e.g., y), that allows the device to specify positions in a plane.

Computer system 900 may implement the techniques described herein using customized hard-wired logic, one or more ASICs or FPGAs, firmware and/or program logic which in combination with the computer system causes or programs computer system 900 to be a special-purpose machine. According to one embodiment, the techniques herein are performed by computer system 900 in response to processor 904 executing one or more sequences of one or more instructions contained in main memory 906. Such instructions may be read into main memory 906 from another storage medium, such as storage device 910. Execution of the sequences of instructions contained in main memory 906 causes processor 904 to perform the process steps described herein. In alternative embodiments, hard-wired circuitry may be used in place of or in combination with software instructions.

The term “storage media” as used herein refers to any non-transitory media that store data and/or instructions that cause a machine to operate in a specific fashion. Such storage media may comprise non-volatile media and/or volatile media. Non-volatile media includes, for example, optical or magnetic disks, such as storage device 910. Volatile media includes dynamic memory, such as main memory 906. Common forms of storage media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM, NVRAM, any other memory chip or cartridge, content-addressable memory (CAM), and ternary content-addressable memory (TCAM).

Storage media is distinct from but may be used in conjunction with transmission media. Transmission media participates in transferring information between storage media. For example, transmission media includes coaxial cables, copper wire and fiber optics, including the wires that comprise bus 902. Transmission media can also take the form of acoustic or light waves, such as those generated during radio-wave and infra-red data communications.

Various forms of media may be involved in carrying one or more sequences of one or more instructions to processor 904 for execution. For example, the instructions may initially be carried on a magnetic disk or solid state drive of a remote computer. The remote computer can load the instructions into its dynamic memory and send the instructions over a telephone line using a modem. A modem local to computer system 900 can receive the data on the telephone line and use an infra-red transmitter to convert the data to an infra-red signal. An infra-red detector can receive the data carried in the infra-red signal and appropriate circuitry can place the data on bus 902. Bus 902 carries the data to main memory 906, from which processor 904 retrieves and executes the instructions. The instructions received by main memory 906 may optionally be stored on storage device 910 either before or after execution by processor 904.

Computer system 900 also includes a communication interface 918 coupled to bus 902. Communication interface 918 provides a two-way data communication coupling to a network link 920 that is connected to a local network 922. For example, communication interface 918 may be an integrated services digital network (ISDN) card, cable modem, satellite modem, or a modem to provide a data communication connection to a corresponding type of telephone line. As another example, communication interface 918 may be a local area network (LAN) card to provide a data communication connection to a compatible LAN. Wireless links may also be implemented. In any such implementation, communication interface 918 sends and receives electrical, electromagnetic or optical signals that carry digital data streams representing various types of information.

Network link 920 typically provides data communication through one or more networks to other data devices. For example, network link 920 may provide a connection through local network 922 to a host computer 924 or to data equipment operated by an Internet Service Provider (ISP) 926. ISP 926 in turn provides data communication services through the world wide packet data communication network now commonly referred to as the “Internet” 928. Local network 922 and Internet 928 both use electrical, electromagnetic or optical signals that carry digital data streams. The signals through the various networks and the signals on network link 920 and through communication interface 918, which carry the digital data to and from computer system 900, are example forms of transmission media.

Computer system 900 can send messages and receive data, including program code, through the network(s), network link 920 and communication interface 918. In the Internet example, a server 930 might transmit a requested code for an application program through Internet 928, ISP 926, local network 922 and communication interface 918.

The received code may be executed by processor 904 as it is received, and/or stored in storage device 910, or other non-volatile storage for later execution.

### 6. Cabling Determination Architecture

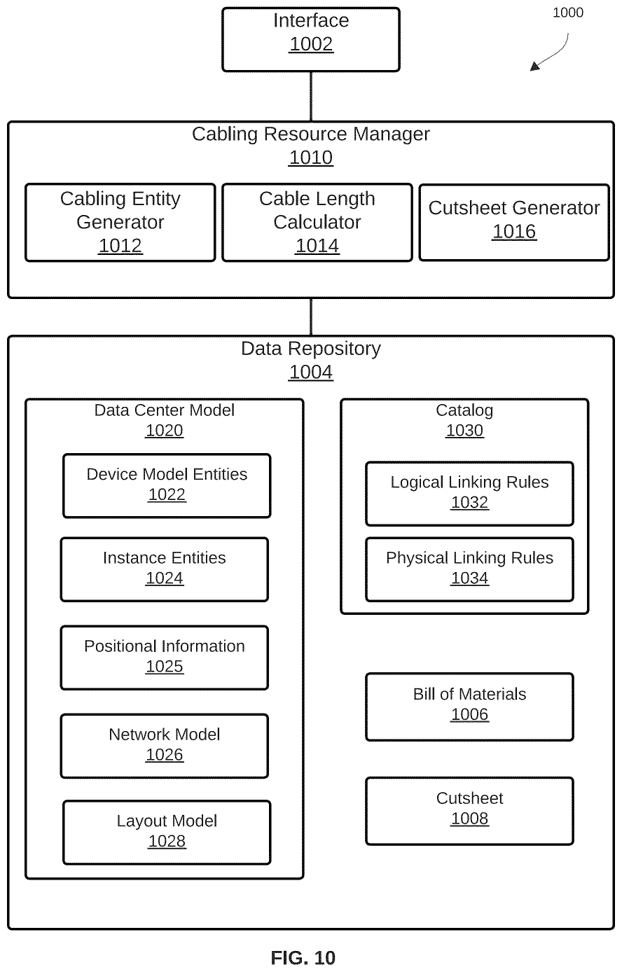

FIG. 10 illustrates a system 1000 in accordance with one or more embodiments. As illustrated in FIG. 10, system 1000 includes an interface 1002, a data repository 1004, and a cabling resource manager 1010. In one or more embodiments, the system 1000 may include more or fewer components than the components illustrated in FIG. 10. The components illustrated in FIG. 10 may be local to or remote from each other. The components illustrated in FIG. 10 may be implemented in software and/or hardware. Each component may be distributed over multiple applications and/or machines. Multiple components may be combined into one application and/or machine. Operations described with respect to one component may instead be performed by another component.

In one or more embodiments, interface 1002 refers to hardware and/or software configured to facilitate communications between a user and the cabling resource manager 1010. Interface 1002 renders user interface elements and receives input via user interface elements. Examples of interfaces include a graphical user interface (GUI), a command line interface (CLI), a haptic interface, and a voice command interface. Examples of user interface elements include checkboxes, radio buttons, dropdown lists, list boxes, buttons, toggles, text fields, date and time selectors, command lines, sliders, pages, and forms.

In an embodiment, different components of interface 1002 are specified in different languages. The behavior of user interface elements is specified in a dynamic programming language such as JavaScript. The content of user interface elements is specified in a markup language, such as hypertext markup language (HTML) or XML User Interface Language (XUL). The layout of user interface elements is specified in a style sheet language such as Cascading Style Sheets (CSS). Alternatively, interface 1002 is specified in one or more other languages, such as Java, C, or C++.

In one or more embodiments, a data repository 1004 is any type of storage unit and/or device (e.g., a file system, database, collection of tables, or any other storage mechanism) for storing data. Furthermore, a data repository 1004 may include multiple different storage units and/or devices. The multiple different storage units and/or devices may or may not be of the same type or located at the same physical site. Furthermore, a data repository 1004 may be implemented or executed on the same computing system as the cabling resource manager 1010. Additionally, or alternatively, a data repository 1004 may be implemented or executed on a computing system separate from the cabling resource manager 1010. The data repository 1004 may be communicatively coupled to the cabling resource manager 1010 via a direct connection or via a network.

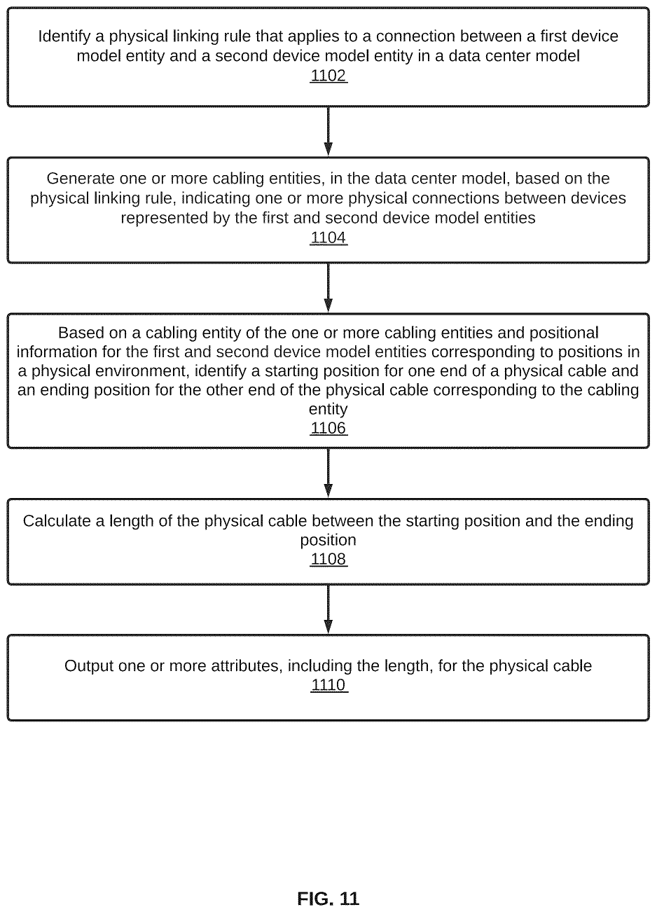

In one or more embodiments, the cabling resource manager 1010 refers to hardware and/or software configured to perform operations described herein for determining physical cabling resources for a data center based on a data center model. Examples of operations for determining physical cabling resources for a data center based on a data center model are described below with reference to FIG. 11.

The cabling resource manager 1010 may access or modify a data center model 1020 to generate a bill of materials 1006. The bill of materials 1006 may be a document, a database, or other data structure that includes entries or records for one or more physical cables to be used in installing computing and networking resources in a data center. An entry or record for one cable may include one or more cabling attributes of the cable, such as length, connector type, shielding level, speed, and cable type. The cabling resource manager 1010 may output the bill of materials in a human-readable format. The cabling resource manager 1010 may provide the bill of materials for an order for the physical cables.

The data center model 1020 represents the logical and physical components of a data center and connections among the components. The data center model 1020 includes a set of device model entities 1022. A device model entity, also referred to as a logical device model, represents a type of device that will be used in the data center but does not represent a specific physical instance of a device in the data center model. A device model entity may include one or more attributes that define the type of device. For example, a rack model entity may have attributes describing a shape for a rack as well as a rack type and may include an identifier for a rack position. A device model entity may have attributes describing a device type, a device platform, a device role, and an identifier for an associated rack model entity. Examples of devices that may be represented by device model entities include racks, ports, processors, network interface cards, patch panels, switches, and storage devices.

The device model entities may include a set of linking entities. A linking entity may represent a logical connection between two device model entities. A logical connection between two device model entities indicates that two physical devices represented by the two device model entities will be communicatively coupled in the data center without specifying physical components that enable the communication. A linking entity may include two attributes that identify logical ports respectively associated with two device model entities that are logically connected.

The data center model 1020 includes a set of instance entities 1024. An instance entity represents a specific physical instance of a model entity. For example, a rack instance entity is associated with a rack model entity and represents a physical rack instance with a unique serial number.

Instance entities 1024 may include a set of device instance entities. A device instance entity represents a unique physical device and may be assigned with a compatible device model entity in the data center model. For example, once assigned to a device model entity, a device instance entity may include a serial number attribute and an attribute that refers to the assigned device model entity.

The data center model 1020 includes positional information 1025. Positional information is associated with a device model entity and includes location information for a device within the data center. Positional information may include, for example, a floor position, a rack number, a floor row, and a room in the data center. Positional information does not include specific coordinates within a physical environment.

The data center model 1020 includes a network model 1026. The network model may include information describing the connections among the devices in the data center. The network model may indicate a network topology associated with the device model entities in the data center model. The network model may include information describing a set of roles that groups of devices may perform in the network, such as spine nodes, leaf nodes, and client groups.

The network model may include a set of port instance entities. A port instance entity represents a physical port in a physical device and is associated with a device model entity. A port instance entity does not have a serial number but may include a unique identifier within the data center model that may be mapped to a corresponding unique port on a unique physical device. A physical port may be used to implement one or more logical ports. A port instance entity may, accordingly, be associated with two or more logical ports.

The network model may include a set of cabling entities. A cabling entity represents a physical cable that will be used to create a physical connection between two physical devices. The physical connection may implement a logical connection or a part of a logical connection. A cabling entity includes one or attributes that describe the corresponding physical cable, such as length, connector type, shielding level, speed, and cable type. The cabling entity includes identifiers for the two-port instance entities associated with the pair of device model entities connected in the data center model.

The data center model 1020 includes a layout model 1028. The layout model may include the physical parameters of the physical environment that will house the data center. The physical parameters may include the dimensions of one or more rooms that will house the physical devices of the data center. The physical parameters may include the coordinates and dimensions of fixed building structures, such as walls, doors, staircases, passageways, and spaces that cabling may extend through but that will otherwise not house equipment.

The cabling resource manager 1010 may include one or more functional components, such as a cabling entity generator 1012, a cable length calculator 1014, and a cutsheet generator 1016. More, fewer, or other functional components may be used to perform the operations of the cabling resource manager 1010.

The cabling entity generator 1012 refers to hardware and/or software configured to perform operations described herein for generating cabling entities based on the linking entities, the layout model, and the positional information. The cabling entity generator 1012 may determine that a linking entity corresponds to a physical connection from a first device to an intermediate device and from the intermediate device to a second device, so at least two physical cables are needed to implement the physical connection. The cabling entity generator may generate at least two cabling entities corresponding to the at least two physical cables.

The cable length calculator 1014 refers to hardware and/or software configured to perform operations described herein for calculating the length of a physical cable needed to connect two physical devices. The cable length calculator calculates a cable length based, in part, on the positional information for the two ports to be connected and the layout model.

The cutsheet generator 1016 refers to hardware and/or software configured to perform operations described herein for generating a cutsheet 1008. The cutsheet 1008 may be a data structure, such as a database or a spreadsheet, that includes entries corresponding to the direct physical connections between two physical ports. The cutsheet generator may access the cabling entities in the data center model. Based on the cabling entities, the cutsheet generator may output entries from the cutsheet that indicate pairs of physical port identifiers that are to be physically connected. A human cabling technician may refer to the cutsheet when physically connecting ports in the data center.

The cabling resource manager 1010 may refer to a catalog 1030. The catalog 1030 includes information used in generating the data center model 1020. For example, the catalog 1030 may include one or more logical linking rules 1032. The logical linking rules may specify what devices may be connected to each other according to the roles assigned to the respective devices according to the network model.

The catalog may include one or more physical linking rules 1034. A physical linking rule may indicate when one or more intermediate devices are to be used when implementing an indirect physical connection corresponding to a logical connection. For example, a physical linking rule may specify that when connecting a leaf node and a spine node, a patch panel should be used between the leaf node and the spine node. A physical linking rule may indicate that a direct physical connection corresponding to a logical connection is to be implemented without an intermediate device. A physical linking rule may indicate a set of port numbers on a device having one role that should be connected to another device having another role.

Information describing the data center model and the catalog may be implemented across any of components within the system 1000. However, this information is illustrated within the data repository 1004 for purposes of clarity and explanation.

In an embodiment, system 1000 is implemented on one or more digital devices. The term “digital device” generally refers to any hardware device that includes a processor. A digital device may refer to a physical device executing an application or a virtual machine. Examples of digital devices include a computer, a tablet, a laptop, a desktop, a netbook, a server, a web server, a network policy server, a proxy server, a generic machine, a function-specific hardware device, a hardware router, a hardware switch, a hardware firewall, a hardware firewall, a hardware network address translator (NAT), a hardware load balancer, a mainframe, a television, a content receiver, a set-top box, a printer, a mobile handset, a smartphone, a personal digital assistant (PDA), a wireless receiver and/or transmitter, a base station, a communication management device, a router, a switch, a controller, an access point, and/or a client device.

### 7. Determining Physical Cabling Resources for a Data Center Based on a Data Center Model

FIG. 11 illustrates an example set of operations for determining physical cabling resources for a data center based on a data center model in accordance with one or more embodiments. One or more operations illustrated in FIG. 11 may be modified, rearranged, or omitted. Accordingly, the particular sequence of operations illustrated in FIG. 11 should not be construed as limiting the scope of one or more embodiments.

In an embodiment, the system determines a cabling resource corresponding to a cable to connect two physical devices represented by a first device model entity and a second device model entity in a data center. The system identifies a physical linking rule that applies to a connection between the first device model entity and the second device model entity in a data center model (Operation 1102). The system may determine respective roles assigned to the first and second device model entities based on the values of a role attribute in the respective first and second device model entities. The system then identifies the physical linking rule that applies to the roles. The system may search for or look up a physical linking rule in the catalog that refers to the determined roles.

In an embodiment, the system generates one or more cabling entities in the data center model (Operation 1104). The system determines a number of physical connections needed to realize a physical connection between physical devices that correspond to the first and second device model entities based on the physical linking rule and/or one or more attributes of a device model entity. The system may determine that the identified physical linking rule indicates a direct or indirect physical connection between physical devices. A direct physical connection may correspond to one logical connection. The system may determine that a port instance entity associated with the first device model entity corresponds to two or more logical ports on the first device model entity, indicating that one physical cable is needed to implement a physical connection corresponding to the two or more logical ports, for example, a breakout cable, a Y cable, or a shuffle cable. The system generates a number of cabling entities corresponding to the number of physical connections.

In generating a cabling entity, the system may determine, based on the physical linking rule, that a first physical device is to be directly connected to the second physical device without an intermediate device. Accordingly, the system may generate one cabling entity corresponding to a cable that connects the first physical device to the second physical device. The system may identify a first port instance entity associated with the first device model entity and a second port instance entity associated with the second device model entity. The system may include identifiers of the first and second port instance entities in a cabling entity. The system may associate the cabling entity with the first and second device model entities via the first and second port instance entities.

In generating a cabling entity, the system may determine, based on the physical linking rule, that an intermediate device, such as a patch panel, is to be used when implementing the physical connection. Accordingly, the system may generate a first cabling entity corresponding to a cable that will connect the first physical device and the intermediate device. Additionally, the system may generate a second cabling entity corresponding to a second cable that will connect the intermediate device and the second physical device. The system may identify a first port instance entity associated with the first device model entity. The system may identify respective second and third port instance entities associated with an intermediate device model entity. The system may identify a fourth port instance entity associated with the second device model entity. The system may include the first and second identifiers in a first cabling entity that corresponds to the first cable and the third and fourth identifiers in a second cabling entity that corresponds to the second cable.

In an embodiment, for a cabling entity of the one or more cabling entities, the system identifies a starting position for one end of a physical cable, corresponding to the cabling entity, and an ending position for the other end of the physical cable. The system identifies the starting position and the ending position based on positional information for the first and second device model entities that correspond to positions in a physical environment (Operation 1106). The system may access the positional information and the layout model to determine physical coordinates for the starting position and the ending position. For example, the positional information indicates a floor position, a rack number, and a floor row for a device in a room. The layout model indicates the physical dimensions of the room. The system can convert the positional information into a room coordinate, e.g., at a point 3.2 meters from one wall and 2.7 meters from a perpendicular wall. The system may also calculate a vertical position from the floor or the ceiling to determine a three-dimensional (3D) coordinate for a port.

In an embodiment, the system calculates a length of the physical cable between the starting position and the ending position (Operation 1108). The system can determine a 3D path between the two room coordinates that corresponds to the two ports to be directly connected. A pair of ports may not be connected in a straight line. Cables may be curved between nearby ports, routed around corners, or otherwise include turns from one port to another. For example, the cables from one elevation on a rack may be routed toward a side of the rack and then routed downwardly or upwardly toward other devices. The system may refer to the network model, the layout model, and device cabling instructions to determine a path for a cable according to the room coordinates for the starting and ending positions. For example, the system may determine that the ports to be connected are in the same row. The system may determine that the cable may be routed from one port to a side of the rack, from the side of the rack to a basket tray above the rack, across one or more basket trays of known length, from another basket tray to the side of the other rack having the other port, and from the side of the other rack to the second port.

The system may calculate the length of the 3D path and assign the length as an attribute of the physical cable. The system may add together known lengths of the linear portions of the determined 3D path and adjust the length to include allowances for turns in the cable. The system may adjust the calculated length to accommodate the length of connectors and/or to provide an amount of slack to facilitate the connection process.

In an embodiment, the system outputs one or more attributes, including the length, for the physical cable (Operation 1110). The system may populate a bill of materials data structure with the values of the one or more attributes. When an entry for a particular cable specification already exists in the bill of materials data structure, the system may increase a count for the particular cable specification rather than create a new entry in the bill of materials data structure. The system may include the length and the one or more attributes for the physical cable in a bill of materials. For example, the system may automatically populate an order template in a document or in an ordering system with the values from the bill of materials data structure. The system may generate a bill of materials document that lists the quantities, lengths, and types of cables to be ordered and used in the data center. The document may be printed or transmitted electronically to a supplier.

The system may repeat Operations 1106, 1108, and 1110 for additional cabling entities in the one or more cabling entities.

### 8. Example Embodiment

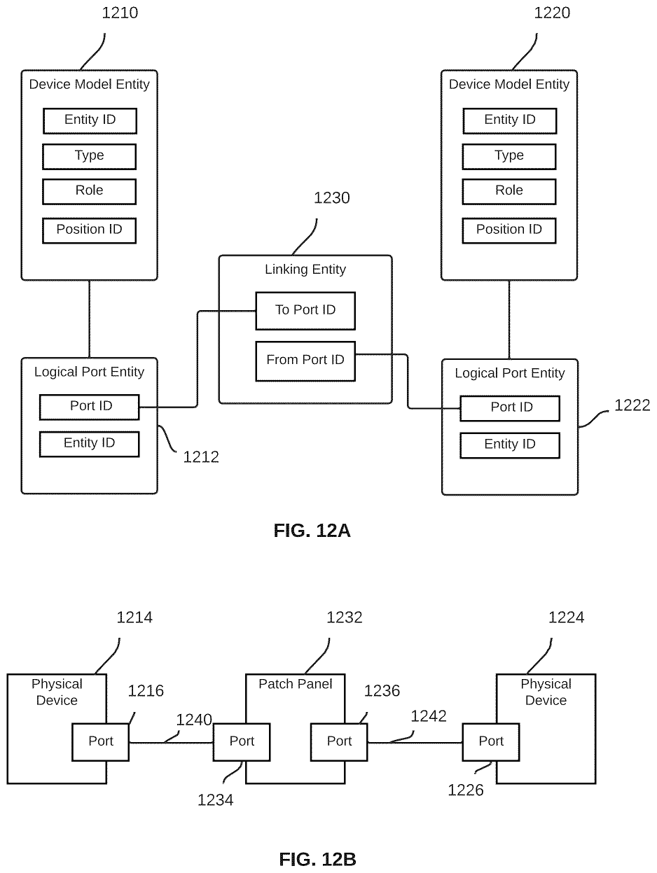

FIG. 12A illustrates a representation of logical components in a data center model in accordance with one or more embodiments. As shown, the data center model includes two device model entities, 1210 and 1220. A device model entity has an entity ID that uniquely identifies the device model entity in the data center model. The device model entity has one or more additional attributes, such as a type of device, a role of the device, and a position identifier.

Device model entity 1210 is associated with a logical port entity 1212. The logical port entity 1212 has a port identifier that uniquely identifies the logical port entity in the data center model and a reference to the device model entity ID for the device model entity that is associated with the port, e.g., device model entity 1210. Similarly, device model entity 1220 is associated with a logical port entity 1222.

The illustrated device model entities are logically connected. The logical connection is represented by a linking entity 1230. The linking entity includes the port identifiers of the respective logical ports for the device model entities that are logically connected.

FIG. 12B is a block diagram illustrating an example of a physical connection between devices in a data center. The physical connection may correspond to the logical connection represented by the linking entity 1230. Physical device 1214 is a device having (a) the characteristics of a device represented by device model entity 1210 and (b) a physical port 1216. Similarly, physical device 1224 is a device having (a) the characteristics of a device represented by device model entity 1220 and (b) a physical port 1226.

In the illustrated example, the system has determined that a patch panel 1232 is needed to connect physical device 1214 to physical device 1224. The patch panel 1232 has two ports, 1234 and 1236, used to implement the connection between physical devices 1214 and 1224. Accordingly, two physical cables, 1240 and 1242, are used in the physical connection that implements the logical connection represented by the linking entity 1230. Prior to the physical cabling operations, the system determines the lengths needed for the cables 1240 and 1242 as described herein.

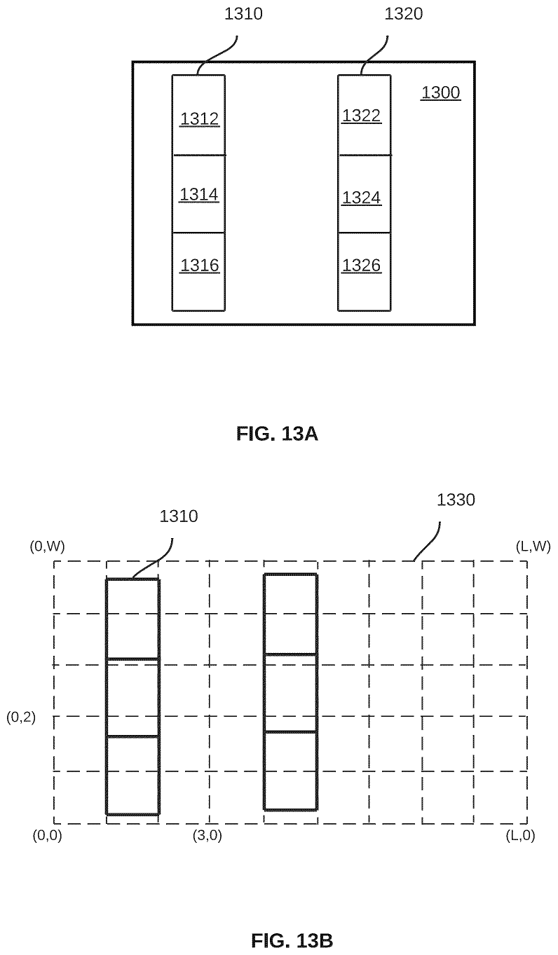

FIG. 13A illustrates a representation of positional information 1300 for a data center model in accordance with one or more embodiments. As shown, a data center model includes two rack rows, 1310 and 1320. Within a rack row are floor positions corresponding to relative positions for a rack within a row. Rack row 1310 shows three floor positions: 1312, 1314, and 1316. A rack in floor position 1312 will be adjacent to a rack in floor position 1314. Similarly, rack row 1320 shows three floor positions: 1322, 1324, and 1326. A rack in floor position 1324 is adjacent to both a rack in floor position 1322 and a rack in floor position 1326. The position information 1300 defines relative positioning for the racks but does not specify a physical position in a physical environment. A vertical position, e.g., rack elevation (not shown), for a physical device may also be included in the positional information, indicating a slot in the rack where a physical device is located.

FIG. 13B illustrates a representation of a layout model 1330 in accordance with one or more embodiments. The layout model 1330 defines physical parameters of a physical environment where the devices of a data center will be placed. For example, layout model 1330 defines a floor area that is W units wide and L units long. The layout model 1330 may include a grid, shown by the dotted lines, defined by a coordinate system. When the system determines the placement of the racks and rack rows in the layout model, the system can then determine coordinates for the racks within the physical environment and the coordinates for device and ports within a rack.

### 9. Practical Applications, Advantages, and Improvements

Conventional methods of determining the cable resources needed for use in a data center may result in inefficiencies in cost, materials, and/or labor. Cabling installers can manually add terminators to cables during installation to achieve a preferred cable length for a given connection at a considerable increase in the amount of time needed to create the connections. Pre-terminated cables may be ordered ahead of the cabling operations; however, standard, commercially available cable lengths may not meet the needs of a large-scale data center. In addition, the large numbers of cables needed, e.g., tens of thousands, hundreds of thousands, or more, generally mean that the cables need to be ordered in advance of the cabling operations to allow the supplier to create and ship the cables in time for the cabling operations.

One or more embodiments leverage the information in a data center model to generate the information needed to create a bill of materials for the cabling resources. The system uses information about logical connections between logical device model entities, physical linking rules, and information about the physical layout of the environment where the data center equipment will be operating to identify the specific lengths, numbers, and types of cables needed to implement physical connections corresponding to the logical connections.

### 10. Miscellaneous; Extensions

Unless otherwise defined, terms (including technical and scientific terms) are to be given their ordinary and customary meaning to a person of ordinary skill in the art and are not to be limited to a special or customized meaning unless expressly so defined herein.

This application may include references to certain trademarks. Although the use of trademarks is permissible in patent applications, the proprietary nature of the marks should be respected and every effort made to prevent their use in any manner that might adversely affect their validity as trademarks.

Embodiments are directed to a system with one or more devices that include a hardware processor and that are configured to perform any of the operations described herein and/or recited in any of the claims below.

In an embodiment, one or more non-transitory, computer-readable storage media comprises instructions that, when executed by one or more hardware processors, cause performance of any of the operations described herein and/or recited in any of the claims.

In an embodiment, a method comprises operations described herein and/or recited in any of the claims, the method being executed by at least one device, including a hardware processor.

Any combination of the features and functionalities described herein may be used in accordance with one or more embodiments. In the foregoing specification, embodiments have been described with reference to numerous specific details that may vary from implementation to implementation. The specification and drawings are, accordingly, to be regarded in an illustrative rather than a restrictive sense. The sole and exclusive indicator of the scope of patent protection, and what is intended by the applicants to be the scope of patent protection, is the literal and equivalent scope of the set of claims that issue from this application, in the specific form that such claims issue, including any subsequent correction.

What is claimed is:

1. A method comprising:
accessing a data center model comprising:
a plurality of device model entities wherein the plurality of device model entities comprise a first device model entity and a second device model entity;
positional information, for the plurality of device model entities, corresponding to positions in a physical environment;
accessing a set of physical linking rules wherein a physical linking rule defines physical connections between a first group of one or more device model entities and a second group of one or more device model entities;
identifying a first physical linking rule, of the set of physical linking rules, that applies to the first device model entity and the second device model entity;
based at least on the first physical linking rule, generating one or more cabling entities indicating one or more physical connections between physical devices represented by the first device model entity and the second device model entity; and
based at least on the one or more cabling entities and the positional information for the plurality of device model entities corresponding to positions in the physical environment, outputting a set of one or more attributes for one or more physical cables corresponding to the one or more cabling entities;
wherein the method is performed by at least one device including a hardware processor.

2. The method of claim 1, wherein generating the one or more cabling entities comprises:
determining a first set of port instance entities associated with the first device model entity and a second set of port instance entities associated with the second device model entity; and
assigning to a first cabling entity: (a) a first port instance entity identifier for a first port instance entity in the first set of port instance entities, and (b) a second port instance entity identifier for a second port instance entity in the second set of port instance entities.

3. The method of claim 1, wherein:
the first physical linking rule indicates a first set of physical connections between the first device model entity and an intermediate device, and a second set of physical connections between the intermediate device and the second device model entity;
and wherein generating the one or more cabling entities comprises:
generating a first cabling entity indicating a first physical connection between the first device model entity and the intermediate device; and
generating a second cabling entity indicating a second physical connection between the intermediate device and the second device model entity.

4. The method of claim 3, wherein the intermediate device comprises at least one of a passive network device, a patch panel, a transceiver, a connector, and a splitter.

5. The method of claim 1, wherein:
generating the one or more cabling entities comprises determining a cable type for a physical connection between the first device model entity and the second device model entity based on at least one of: a first type of the first device model entity; a second type of the second device model entity; a third type of a first port of the first device model entity; a fourth type of a second port of the second device model entity.

6. The method of claim 1, wherein outputting the set of one or more cable attributes for a physical cable, of the one or more physical cables, comprises:
calculating, based on a first cabling entity of the one or more cabling entities and the positional information corresponding to positions in the physical environment, a three-dimensional (3D) physical connection path between the first device model entity and the second device model entity; and
determining a physical length of the 3D physical connection path, wherein the physical length corresponds to a length attribute of the set of one or more cable attributes.

7. The method of claim 6, wherein calculating the 3D physical connection path between the first device model entity and the second device model entity comprises:
determining that the first cabling entity indicates a physical connection between a first port of the first device model entity and a second port of the second device model entity; and
calculating the 3D physical connection path between the first port and the second port.

8. The method of claim 6, wherein calculating the 3D physical connection path between the first device model entity and the second device model entity is further based on 3D positional information of cabling racks configured to hold cables in the physical environment.

9. The method of claim 1, wherein outputting the set of one or more cable attributes for a physical cable, of the one or more physical cables, comprises:
generating a bill of materials that specifies a list of physical cables to be used in the physical environment and the corresponding cable attributes of the physical cables, the list of physical cables comprising one or more physical cables implementing the physical connection between the first device model entity and the second device model entity.

10. The method of claim 9, further comprising: initiating an order for the list of physical cables based on the bill of materials.

11. The method of claim 1, wherein the data center model comprises:
a plurality of device instance entities, assigned respectively with the plurality of device model entities, wherein a first device instance entity represents a first device instance and is assigned with the first device model entity, and a second device instance entity represents a second device instance and is assigned with the second device model entity;
and the method further comprises:
based on the data center model comprising the one or more cabling entities:
generating a cutsheet, the cutsheet indicating the one or more physical connections between the first device instance and the second device instance.

12. The method of claim 1, wherein the data center model comprises a network model and a layout model, wherein the network model indicates a network topology associated with the plurality of device model entities, and the layout model indicates physical parameters of the physical environment.

13. One or more non-transitory computer readable media comprising instructions that, when executed by one or more hardware processors, cause performance of operations comprising:
accessing a data center model comprising:
a plurality of device model entities wherein the plurality of device model entities comprise a first device model entity and a second device model entity;
positional information, for the plurality of device model entities, corresponding to positions in a physical environment;
accessing a set of physical linking rules wherein a physical linking rule defines physical connections between a first group of one or more device model entities and a second group of one or more device model entities;
identifying a first physical linking rule, of the set of physical linking rules, that applies to the first device model entity and the second device model entity;
based at least on the first physical linking rule, generating one or more cabling entities indicating one or more physical connections between physical devices represented by the first device model entity and the second device model entity; and
based at least on the one or more cabling entities and the positional information for the plurality of device model entities corresponding to positions in the physical environment, outputting a set of one or more attributes for one or more physical cables corresponding to the one or more cabling entities.

14. The one or more non-transitory computer readable media of claim 13, wherein generating the one or more cabling entities comprises:
determining a first set of port instance entities associated with the first device model entity and a second set of port instance entities associated with the second device model entity; and
assigning to a first cabling entity: (a) a first port instance entity identifier for a first port instance entity in the first set of port instance entities, and (b) a second port instance entity identifier for a second port instance entity in the second set of port instance entities.

15. The one or more non-transitory computer readable media of claim 13, wherein:
the first physical linking rule indicates a first set of physical connections between the first device model entity and an intermediate device, and a second set of physical connections between the intermediate device and the second device model entity;
and wherein generating the one or more cabling entities comprises:
generating a first cabling entity indicating a first physical connection between the first device model entity and the intermediate device; and
generating a second cabling entity indicating a second physical connection between the intermediate device and the second device model entity.

16. The one or more non-transitory computer readable media of claim 13, wherein outputting the set of one or more cable attributes for a physical cable, of the one or more physical cables, comprises:
calculating, based on a first cabling entity of the one or more cabling entities and the positional information corresponding to positions in the physical environment, a three-dimensional (3D) physical connection path between the first device model entity and the second device model entity; and
determining a physical length of the 3D physical connection path, wherein the physical length corresponds to a length attribute of the set of one or more cable attributes.

17. The one or more non-transitory computer readable media of claim 13, wherein outputting the set of one or more cable attributes for a physical cable, of the one or more physical cables, comprises:
generating a bill of materials that specifies a list of cables to be used in the physical environment and the corresponding cable attributes of the cables, the list of cables comprising one or more cables implementing the physical connection between the first device model entity and the second device model entity.

18. A system comprising:
one or more hardware processors;
one or more non-transitory computer-readable media; and
program instructions stored on the one or more non-transitory computer-readable media that, when executed by the one or more hardware processors, cause the system to perform operations comprising:
accessing a data center model comprising:
a plurality of device model entities wherein the plurality of device model entities comprise a first device model entity and a second device model entity;
positional information, for the plurality of device model entities, corresponding to positions in a physical environment;
accessing a set of physical linking rules wherein a physical linking rule defines physical connections between a first group of one or more device model entities and a second group of one or more device model entities;
identifying a first physical linking rule, of the set of physical linking rules, that applies to the first device model entity and the second device model entity;
based at least on the first physical linking rule, generating one or more cabling entities indicating one or more physical connections between physical devices represented by the first device model entity and the second device model entity; and
based at least on the one or more cabling entities and the positional information for the plurality of device model entities corresponding to positions in the physical environment, outputting a set of one or more attributes for one or more physical cables corresponding to the one or more cabling entities.

19. The system of claim 18, wherein generating the one or more cabling entities comprises:
determining a first set of port instance entities associated with the first device model entity and a second set of port instance entities associated with the second device model entity; and
assigning to a first cabling entity: (a) a first port instance entity identifier for a first port instance entity in the first set of port instance entities, and (b) a second port instance entity identifier for a second port instance entity in the second set of port instance entities.

20. The system of claim 18, wherein:
the first physical linking rule indicates a first set of physical connections between the first device model entity and an intermediate device, and a second set of physical connections between the intermediate device and the second device model entity;
and wherein generating the one or more cabling entities comprises:
generating a first cabling entity indicating a first physical connection between the first device model entity and the intermediate device; and
generating a second cabling entity indicating a second physical connection between the intermediate device and the second device model entity.
